(19) United States
(12) Patent Application Publication
(10) Pub. No.: US 2022/0355316 A1
(43) Pub. Date: Nov. 10, 2022

(54) MIST DEPOSITION APPARATUS AND MIST DEPOSITION METHOD

(71) Applicant: NIKON CORPORATION, Tokyo (JP)

(72) Inventors: Yoshiaki KITO, Kamakura-shi (JP); Hiroshi KAJIYAMA, Yokohama-shi (JP); Yasutaka NISHI, Tokyo (JP); Kotaro OKUI, Hachioji-shi (JP)

(73) Assignee: NIKON CORPORATION, Tokyo (JP)

(21) Appl. No.: 17/869,253

(22) Filed: Jul. 20, 2022

Related U.S. Application Data
(63) Continuation of application No. PCT/JP2021/001749, filed on Jan. 20, 2021.

(30) Foreign Application Priority Data
Jan. 21, 2020 (JP) 2020-007524

(51) Int. Cl. B05B 5/03; B05B 5/00; B05B 5/08; B05B 5/053; B05C 5/02; B05D 1/04

(52) U.S. Cl. CPC B05B 5/03; B05B 5/005; B05B 5/082; B05B 5/0533; B05C 5/0208; B05D 1/04

(57) ABSTRACT

A deposition apparatus supplies mist containing fine particles to a substrate and forms a film including the fine particles on a substrate surface, and includes an air guide member that covers at least a portion of the substrate surface, and a mist supplying section that supplies mist to a space between the substrate surface and the air guide member. The mist supplying section includes a charge applying section, which applies a positive or negative charge to the mist, and a mist ejecting section, which ejects the mist charged by the mist applying section into the space. The air guide member has a wall surface facing the substrate surface, and the deposition apparatus includes an electrostatic field generating section that causes a potential having a same sign as the mist charged by the charge applying section to be generated by the wall surface.

This application is a Continuation of International Application No. PCT/JP2021/001749 filed on Jan. 20, 2021, which is based upon and claims the benefit of priority from Japanese Patent Application No. 2020-007524 filed on Jan. 21, 2020, the contents of which are incorporated herein by reference.

### TECHNICAL FIELD

The present invention relates to a mist deposition apparatus and mist deposition method for spraying mist, which is obtained by atomizing a solution containing fine material particles (nanoparticles), onto a processing target substrate to form a thin film of a material substance made of the fine particles on the surface of the processing target substrate.

### BACKGROUND ART

In an electronic device manufacturing process, a film deposition step (film deposition process) is implemented to form a thin film, made of various material substances, on the surface of a substrate (processing target object) on which the electronic device is to be formed. There are various techniques for the deposition method in the deposition step, and in recent years, focus has been placed on a mist deposition method that includes spraying the surface of the substrate with mist generated from a solution containing molecules or fine particles (nanoparticles) of a material substance, reacting or evaporating a solvent component contained in the mist (solution) adhered to the substrate, and forming a thin film made of the material substance (metal material, organic material, oxide material, or the like) on the surface of the substrate. An electrostatic spraying deposition method (electrospray deposition technique) such as disclosed in JP 2005-281679 A is known as a deposition method similar to the mist deposition method. The electrostatic spraying deposition method is a method that includes electrostatically charging the liquid to be applied, making the charged liquid into minute droplets (mist) or linear bodies, and adhering this liquid to a target object. JP 2005-281679 A discloses a configuration in which a solution obtained by dissolving a resin for film formation on the surface of an insulating film in a solvent or a dispersion in which resin and inorganic fine particles are dispersed is supplied to a spouting nozzle having capillaries at the tip, and a high voltage is applied to this spouting nozzle while also applying a pressure causing a constant flow rate to the spouting nozzle, thereby spraying charged droplets or linear bodies with diameters from tenths of microns to tens of microns onto the film surface from the capillaries at the tip of the nozzle. Furthermore, in JP 2005-281679 A, the film is placed on a conductive board having a greater surface area than the film and a certain potential difference is provided between this conductive board and the spray nozzle, thereby efficiently attaching the charged droplets or linear bodies to the film surface.

With the electrostatic spraying deposition technique, the droplets or linear bodies sprayed from the capillaries of the spouting nozzle also depend on a distance from the nozzle tip to the film surface or the potential difference between the spouting nozzle and the conductive board, but in JP 2005-281679 A, the diameter of the spouting nozzle tip (capillaries) is preferably set in a range of 0.4 mm to 1 mm and the voltage applied between the spouting nozzle and the conductive board is preferably set in a range from 10 kV to 20 kV, thereby causing the droplets or linear bodies to be ejected from the nozzle tip by an electrostatic repulsive force. Therefore, there is a tendency for the formed film to be thickest at a central portion where an extension line of the capillary of the nozzle tip in the ejection direction intersects with the film surface and for the film thickness to decrease gradually from the center portion toward the periphery. Due to this, in order to form a thin film of resin or inorganic fine particles with a precise and uniform thickness on a large film surface, it is necessary to relatively move the film and the spouting nozzle with high precision and a constant velocity in a two-dimensional plane parallel to the film surface.

### SUMMARY OF THE INVENTION

A first aspect of the present invention is a mist deposition apparatus that sprays a substrate with mist containing fine particles of a material substance to form a film layer of the material substance on a surface of the substrate, the mist deposition apparatus including: a mist generating mechanism that atomizes a solution containing the material nanoparticles and sends out mist gas containing the generated mist; a mist ejecting mechanism that allows the mist gas to flow therein and ejects the mist toward the substrate; an air guide mechanism having an inner wall surface facing the surface of the substrate with a prescribed interval therebetween, in order to cause the mist gas from the mist ejecting mechanism to flow along the surface of the substrate; and a mist guidance mechanism which generates a repulsive force between the mist and an inner wall surface of the air guide member in order to generate an attractive force that attracts the mist to the surface of the substrate.

A second aspect of the present invention is a mist deposition apparatus that sprays a surface of a substrate with mist gas in which mist containing fine particles is carried by a carrier gas to form a thin film of the fine particles on the surface of the substrate, the mist deposition apparatus including: a mist spraying section that has a nozzle opening facing the surface of the substrate across a prescribed interval and ejects the mist gas from the nozzle opening toward the substrate; a mist supplying apparatus that supplies the mist gas to the mist spraying section at a prescribed flow rate and sets the mist gas ejected from the nozzle opening to a first temperature that is lower than an environmental temperature; a moving mechanism that supports the substrate and moves along the surface of the substrate; and a substrate adjusting mechanism that sets the substrate sprayed with the mist gas to a second temperature that is lower than the first temperature.

A third aspect of the present invention is a mist deposition method for spraying a surface of a processing target substrate with mist gas in which mist containing fine particles is carried by carrier gas to form a thin film of the fine particles on the surface of the processing target substrate, the mist deposition method including: setting the temperature, with first temperature adjuster, of the mist gas sprayed from a mist ejecting section toward the surface of the processing target substrate to a first temperature that is higher than 0° C. and less than or equal to 30° C.; setting the temperature, with a second temperature adjuster, of the processing target substrate to a second temperature that is less than or equal to the first temperature; and, while moving the mist ejecting section and the processing target substrate, with a moving mechanism, relative to each other along the surface of the processing target substrate, spraying the surface of the processing target substrate set to the second temperature with the mist gas set to the first temperature.

A fourth aspect of the present invention is a deposition apparatus that supplies mist containing fine particles to a substrate and forms a film including the fine particles on a surface of the substrate, the deposition apparatus including: an air guide member configured to cover at least a portion of the surface of the substrate; and a mist supplying section configured to supply mist to a space between the surface of the substrate and the air guide member, wherein: the mist supplying section includes a charge applying section, which applies a positive or negative charge to the mist, and a mist ejecting section, which ejects the mist charged by the mist applying section into the space; the air guide member has a wall surface facing the surface of the substrate; and the deposition apparatus includes an electrostatic field generating section configured to cause a potential having a same sign as the mist charged by the charge applying section to be generated by the wall surface.

A fifth aspect of the present invention is a deposition apparatus that supplies mist containing fine particles to a substrate and forms a film including the fine particles on a surface of the substrate, the deposition apparatus including: a mist generating section configured to atomize a liquid containing the fine particles to generate the mist; and a mist supplying section configured to supply the mist to the substrate, wherein the mist supplying section includes a temperature adjusting section that sets a temperature of the mist to a first temperature and a substrate temperature adjusting section that sets a temperature of the substrate to a second temperature.

A sixth aspect of the present invention is a conductive film manufacturing apparatus, including: the deposition apparatus of the first aspect or second aspect described above; and a drying section configured to dry the mist deposited on the substrate by the deposition apparatus.

A seventh aspect of the present invention is a deposition method for supplying mist containing fine particles to a substrate and forming a film including the fine particles on a surface of the substrate, the deposition method including: a mist supplying step of charging the mist to be positive or negative with a charge applying section and supplying the charged mist to a space between the surface of the substrate and an air guide member that covers at least a portion of the surface of the substrate with a mist ejecting section; and an electrostatic field generating step of causing a potential having a same sign as the charged mist to be generated by a wall surface of the air guide member facing the surface of the substrate.

An eighth aspect of the present invention is a deposition method for supplying mist containing fine particles to a substrate and forming a film including the fine particles on a surface of the substrate, the deposition method including: a mist generating step of atomizing a liquid containing the fine particles to generate the mist; and a mist supplying step of supplying the mist to the substrate, wherein the mist supplying step includes setting a temperature of the mist to a first temperature with a temperature adjusting section and setting a temperature of the substrate to a second temperature with a substrate temperature adjusting section.

A ninth aspect of the present invention is a conductive film manufacturing method including: a depositing step of depositing a conductive film material on the substrate using the deposition method of the fourth aspect or fifth aspect described above; and a drying step of drying the substrate on which the film has been deposited.

### BRIEF DESCRIPTION OF DRAWINGS

FIG. 1 shows a schematic overall configuration of a mist deposition apparatus MDE according to a first embodiment;

FIG. 2 is a detailed perspective view of the exterior of the mist depositing section of the mist deposition apparatus MDE shown in FIG. 1;

FIG. 3A is a front view of the mist ejecting section in the mist depositing section;

FIG. 3B is a cross-sectional view taken along the line k1-k2 in FIG. 3A;

FIG. 4 shows a schematic overall configuration of the mist depositing section of the mist deposition apparatus MDE according to a first modification of the first embodiment;

FIG. 5 is a partial cross-sectional view when the rotating drum DR and a chamber section 40 are cleaved by a plane that includes the line CL and the center line AXo shown in FIG. 4, and represents the configuration according to a second modification of the first embodiment;

FIG. 6 shows a schematic overall configuration of the mist deposition apparatus MDE according to a second embodiment;

FIG. 7 shows a detailed configuration of a nanoparticle deposition smoothing section in the mist deposition apparatus MDE shown in FIG. 6;

FIG. 8 schematically shows a configuration of a preliminary experimentation apparatus for checking the function and effect of the deposition smoothing section of FIG. 7;

FIG. 9 is a graph showing an experimental result of Preliminary Experiment 1 investigating the frequency dependency when an AC electric field is applied to the liquid film containing ITO nanoparticles, using the preliminary experimentation apparatus of FIG. 8;

FIG. 10 is a graph showing an experimental result of Preliminary Experiment 2 investigating the dependency on the electrical field strength when an AC electric field is applied to the liquid film containing ITO nanoparticles, using the preliminary experimentation apparatus of FIG. 8;

FIG. 11 is a graph showing an experimental result of Preliminary Experiment 3 investigating the frequency dependency caused by differences in the particle size of the nanoparticles, when an AC electric field is applied to the liquid film containing ITO nanoparticles, using the preliminary experimentation apparatus of FIG. 8;

FIGS. 12A, 12B, and 12C show several examples of waveforms of an AC voltage Ev applied between the electrode plates Ef1 to Ef4 and an electrode plate Em by an AC electric field generating section 90 of the mist deposition apparatus shown in FIG. 6 or 7;

FIG. 13 is an overhead view and a frontal view showing the configuration of the deposition smoothing section (electrophoresis applying section) according to a fifth modification;

FIG. 14 shows a schematic overall configuration of the mist deposition apparatus MDE according to a third embodiment;

FIG. 15 shows waveforms of the AC electric field applied to each of the deposition smoothing section (electrophoresis applying section) after mist deposition and the mist guidance mechanism provided in the mist depositing section of the mist deposition apparatus of FIG. 14;

FIG. 16 is a circuit diagram showing an example of a detailed circuit configuration of an AC electric field generating section 92 shown in FIG. 14;

FIG. 17 shows a schematic configuration of the experimentation apparatus that can check whether electrophoresis occurs in the solution Lq of ITO nanoparticles crystallized such that the exterior shapes are rectangular parallelepiped shapes;

FIG. 18 is a chart showing the experimental results obtained using the experimentation apparatus of FIG. 17;

FIG. 19 shows a schematic overall configuration of the mist deposition apparatus MDE according to a fourth embodiment;

FIG. 20 is a perspective view of a schematic configuration of the preliminary experimentation apparatus for checking the effect of the mist deposition technique according to the fourth embodiment;

FIG. 21 is a graph showing the relationship between the nanoparticle film thickness and the substrate temperature, obtained through experimentation by the preliminary experimentation apparatus of FIG. 20;

FIG. 22 shows a schematic configuration of the mist depositing section of the mist deposition apparatus MDE according to a fifth embodiment;

FIG. 23 is a perspective view of a schematic configuration of the mist deposition apparatus MDE according to a sixth modification obtained by modifying the mist deposition apparatus MDE of FIG. 19;

FIGS. 24A and 24B show a configuration of a valve mechanism 310 for high-speed switching between a supply state and a non-supply state of the mist gas Msg to the supplementary mist spraying section SMD shown in FIG. 23;

FIG. 25 is a partial cross-sectional view of a detailed configuration of a mist generating section 14 shown in FIG. 1, as a seventh modification; and

FIG. 26 shows a planar arrangement of four ultrasonic oscillators 14C1 to 14C4 arranged on the floor portion of an outer container 14D of the mist generating section 14 shown in FIG. 25.

### DESCRIPTION OF THE INVENTION

Preferred embodiments of a mist deposition apparatus and mist deposition method according to the present invention will be presented and described below with reference to the accompanying drawings. The present invention is not limited to these embodiments, and various modifications and improvements could be adopted therein without departing from the essence and gist of the present invention. That is, the configurational elements mentioned below include components that could be easily envisioned by someone skilled in the art and components substantially identical thereto, and it is possible to combine the configurational elements described below as desired. Furthermore, the various configurational elements can be omitted, replaced, or changed without deviating from the scope of the present invention.

### First Embodiment

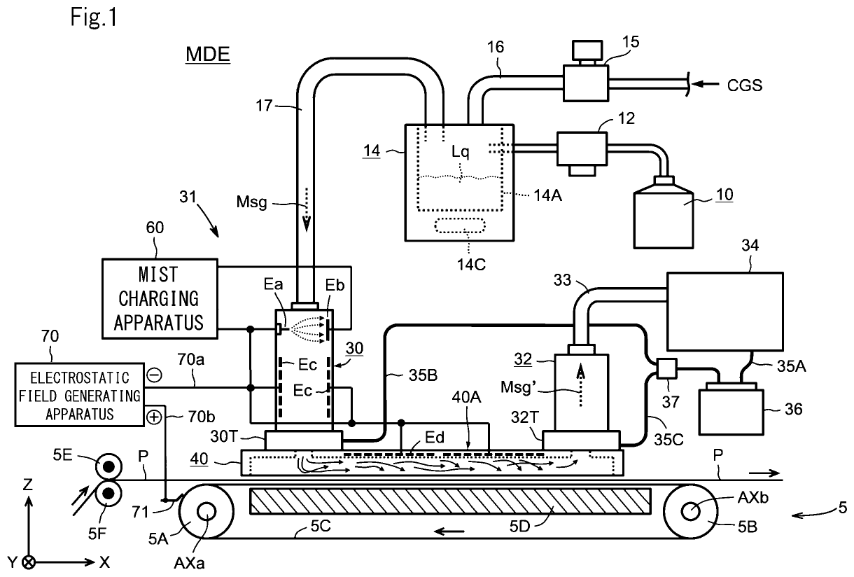

FIG. 1 shows a schematic overall configuration of a mist deposition apparatus MDE according to a first embodiment. In FIG. 1, unless otherwise specified, an XYZ orthogonal coordinate system is established in which the direction of gravity is the Z-direction; the feeding direction, indicated by the arrow shown in FIG. 1, of a flexible sheet substrate P (also referred to simply as the substrate P) serving as a processing target substrate is the X-direction; the width direction of the sheet substrate P, which is orthogonal to the feeding direction, is the Y-direction; and the surface of the sheet substrate P during the mist deposition is in a horizontal plane that is parallel to the XY-plane in the present embodiment. In the present embodiment, the sheet substrate P is a flexible sheet with a thickness approximately from hundreds of micrometers to tens of micrometers, with a resin such as PET (polyethylene terephthalate), PEN (polyethylene naphthalate), or polyimide, which is long in the X-direction, as the base material, but the sheet substrate P may be made of other materials such as a metal foil formed by thinly rolling metal materials such as stainless steel, aluminum, brass, and copper; an ultra-thin glass sheet with a thickness of 100 μm or less to give flexibility; or a plastic sheet containing cellulose nanofibers, for example. The sheet substrate P does not necessarily need to be long, and may be a single-wafer sheet board with standardized long-side and short-side dimensions such as A4 size, A3 size, B4 size, and B3 size, or a non-standard amorphous single-wafer sheet board.

As shown in FIG. 1, the mist deposition apparatus MDE according to the present embodiment is schematically formed by a feeding unit (feeding section) 5 that supports the sheet substrate P and feeds the sheet substrate P in the X direction; a solution tank 10 that stores a solution (dispersion or liquid) Lq in which nanoparticles serving as the material substance of the film deposition are dispersed; a mist generating section 14 that efficiently generates mist with a particle size of approximately several micrometers to tens of micrometers from the solution Lq; a mist ejecting section 30 that is supplied with a mist gas Msg, in which mist generated by the mist generating section 14 is carried by a carrier gas CGS, via a flexible pipe 17 and sprays the mist gas Msg toward the sheet substrate P; a mist recovering section 32 that recovers the mist gas Msg containing the mist that is floating without being adhered to the sheet substrate P; and a chamber section 40 provided in a manner to cover the mist ejecting section 30, the mist recovering section 32, and the sheet substrate P supported by the feeding unit 5 in order to restrict leakage of the mist gas Msg to the outside atmosphere (outside the apparatus). The following describes the configuration of each section in further detail.

The feeding unit 5 shown in FIG. 1 includes a roller 5A that rotates on a central axis AXa parallel to the Y-axis; a roller 5B that rotates on a central axis AXb, which is a prescribed distance away from the central axis AXa in the X-direction and arranged parallel to the central axis AXa; an endless belt 5C that spans between the two rollers 5A and 5B and supports the sheet substrate P in a flat state on the top surface of a flat portion; and a support table 5D that is arranged on the back surface side of the flat portion of the belt 5C supporting the sheet substrate P, and supports the belt 5C in a flat state. The Y-direction width of the belt 5C is set to be slightly greater than the Y-direction width (short dimension) of the substrate P, and the belt 5C exerts vacuum suction on the substrate P in a region corresponding to the top surface of the support table 5D and is also feed-driven in a non-contact state (or a low friction state) with the top surface of the support table 5D by a static pressure gas layer (air bearing) generated between the top surface of the support table 5D and the back surface of the belt 5C. The feeding unit 5 having such a configuration is disclosed in WO 2013/150677 A1, for example, and the belt 5C is preferably made of a thin metal board (thin conductive board), such as stainless steel, that can maintain high rigidity and flatness. In order to adhere the sheet substrate P onto the belt 5C without wrinkles, nip rollers 5E and 5F that provide the sheet substrate P with tension in the longitudinal direction are provided on the downstream side (−X-direction side) of the belt 5C.

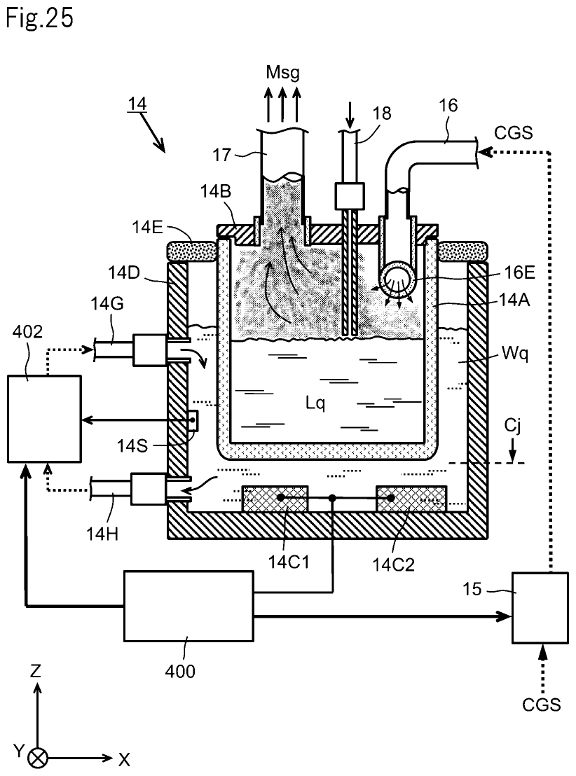

The solvent (including a dispersion) of the solution Lq stored inside the solution tank 10 is pure water, which is easy to handle and highly safe, and the material dispersed in this solvent (pure water) is, for example, nanoparticles that form the material of a transparent conductive film such as indium tin oxide (ITO) dispersed with a desired concentration. The solution Lq in the solution tank 10 is supplied to the mist generating section (mister) 14 intermittently or continuously by a precision pump 12. The mist generating section 14 includes an internal container (cup) 14A) that stores the solution Lq from the precision pump 12 and an ultrasonic oscillator 14C that causes vibrations of approximately 2.4 MHz in the solution Lq via the inner container 14A to generate mist from the liquid surface of the solution Lq, and these components are installed within a sealed outer container 14D (see FIG. 25). Furthermore, the carrier gas CGS adjusted to a prescribed flow rate (or pressure) by a flow rate adjusting valve 15 is supplied through a pipe 16 in the space at the top of the internal container 14A of the mist generating section 14. In the configuration described above, the precision pump 12, the ultrasonic oscillator 14C, and the flow rate adjusting valve 15 each receive instructions from a host controller (computer for integrated control or the like), which is not shown in the drawings, to be driven with suitable drive amounts, timings, intervals, and the like.

In a case where the nanoparticles serving as the deposition material tend to aggregate in pure water, it is possible to restrict aggregation of the nanoparticles and maintain dispersion by including a prescribed concentration of a surfactant in the solvent of the solution Lq. Furthermore, in a case where there is a desire to not include a surfactant in the solution Lq, it is possible to provide an oscillator that provides ultrasonic vibration (frequency of 200 kHz or less) for restricting aggregation of the nanoparticles of the solution Lq in the inner container 14A, as disclosed in WO 2017/154937 A1, for example. When ITO nanoparticles having a non-cuboidal shape (crystals with aligned orientation) created using the method disclosed in WO 2019/138707 A1 or WO 2019/138708 A1 are used as the ITO (indium tin oxide) nanoparticles, it is possible to keep the nanoparticles in a dispersed state without aggregating or precipitating over a long period of time, even in a solution Lq made of pure water that does not contain a surfactant.

The nanoparticles that can be deposited by the mist deposition apparatus MDE can be, in addition to the ITO nanoparticles used as an example, nanoparticles of various materials (conductive materials, insulating materials, or semiconductor materials). Nanoparticles are usually particles smaller than 100 nm, but with mist deposition, the particles can be any size that is smaller than the particle diameter of mist (several micrometers to tens of micrometers) and makes it possible for the particles to be trapped in the mist and carried by the carrier gas CGS. Among metal types, gold nanoparticles, platinum nanoparticles, silver nanoparticles, copper nanoparticles, carbon nanorods (tubes) purified into good conductors, or the like can be used as such nanoparticles; among oxide types, iron oxide nanoparticles, zinc oxide nanoparticles, silicon oxide (silica) nanoparticles, and the like can be used as such nanoparticles; and among nitride types, silicon nitride nanoparticles, aluminum nitride nanoparticles, and the like can be used as such nanoparticles. Furthermore, carbon nanorods (tubes) refined into semiconductors, silicon nanoparticles, or the like can be used as semiconductor types. The silicon nanoparticles may be hydrocarbon-terminated silicon nanoparticles that are deposited (coated) on the surface of the semiconductor layer that forms a pn-junction solar cell to improve efficiency, such as disclosed in WO 2016/185978 A1, for example.

As shown in FIG. 1, the mist generated in the inner container 14A of the mist generating section 14 is carried to flow with the carrier gas CGS through the pipe 17, to be supplied to the mist ejecting section 30 as the mist gas Msg. The carrier gas CGS can be, in addition to clean atmosphere (H₂O: clean air) from which dust (particulates) has been removed, an inert gas such as clean nitrogen (N₂) gas or argon (Ar) gas. In the present embodiment, simple mist deposition is performed in an environment at room temperature and atmospheric pressure, and therefore the carrier gas CGS is clean air or nitrogen gas. However, as disclosed in WO 2016/133131 A1, for example, in a case where the mist gas Msg sprayed from the mist ejecting section 30 onto the sheet substrate P is irradiated with plasma in a state that is not in thermal equilibrium (plasma assist mist deposition method), the carrier gas CGS should be argon gas.

In a case where it is necessary to set the temperature of the mist gas Msg sprayed from the mist ejecting section 30 to be higher (or lower) than room temperature, a temperature adjusting mechanism (heater, cooler, or the like) is provided to adjust the temperature of the carrier gas CGS, the temperature inside the mist generating section 14, or the temperature inside the pipe 17 as necessary. Furthermore, as shown in FIG. 1, the mist generating section 14 (inner container 14A) should be arranged higher than the mist ejecting section 30 in the direction of gravity (Z direction).

The mist gas Msg supplied from the top portion of the mist ejecting section 30 is sprayed onto the substrate P with a prescribed flow rate (air speed) from a slit-shaped opening (nozzle opening) formed in the floor portion of the mist ejecting section 30 facing the sheet substrate P. The nozzle opening is formed with a length sufficient to cover the Y-direction width of the substrate P, or with a length shorter than this width, and with a width of 1 mm to several millimeters in the X direction, which is the longitudinal direction of the substrate P. When the transport (movement) direction of the longitudinal direction of the substrate P is the +X direction, the mist recovering section 32 is arranged on the downstream side of the mist ejecting section 30 with regard to the transport direction of the substrate P. The mist gas Msg sprayed downward (−Z direction) from the nozzle opening in the floor portion of the mist ejecting section 30 flows downstream (+X direction) along the surface of the sheet substrate P through the inside of the chamber section 40 due to the depressurizing effect (negative pressure) in the mist recovering section 32, and during this the mist adheres to the surface of the sheet substrate P such that a thin liquid film is formed by the mist solvent (pure water in the present embodiment) on the surface of the substrate P.

A recovery port (recovery opening) shaped as a slot extending in the Y direction is formed in the floor portion of the mist recovering section 32, and surplus mist gas Msg′ containing the mist that was not adhered to the sheet substrate P flows into the recovery opening to be captured by a mist gas collecting section 34 that has a depressurizing source, such as a vacuum pump, via a pipe 33 connected to the top portion of the mist recovering section 32. The mist gas collecting section 34 (also referred to below simply as the collecting section 34) returns the mist contained in the collected excess mist gas Msg′ to the state of the solution Lq through condensation, and sends this solution Lq out to a collection tank 36 via a tube 35A. The solution Lq stored in the collection tank 36 is suitably provided to fill the solution tank 10 and is reused.

In the present embodiment, as described in detail further below, a droplet collecting section (trap section) 30T is provided at the bottom portion of the mist ejecting section 30 in order to prevent droplets formed by the collection of mist adhered to the inner wall surface of the mist ejecting section 30 from dripping along the inner wall surface and onto the sheet substrate P from the nozzle opening in the floor portion of the mist ejecting section 30. Similarly, a droplet collecting section (trap section) 32T is provided at the bottom portion of the mist recovering section 32 in order to prevent droplets formed by the collection of mist (surplus mist) adhered to the inner wall surface of the mist recovering section 32 from dripping along the inner wall surface and onto the sheet substrate P from the recovery opening in the floor portion of the mist recovering section 32. The droplets collected by the droplet collecting section 30T return to the state of the original solution Lq, and are sucked up by a small pump 37 via a tube 35B and sent to the collection tank 36. Similarly, the droplets collected by the droplet collecting section 32T return to the state of the original solution Lq, and are sucked up by the small pump 37 via a tube 35C and sent to the collection tank 36.

The chamber section 40 is provided with a board-shaped air guide member 40A (also referred to as a skirt member or rectifying member) that forms a prescribed space in the +Z direction from the surface of the sheet substrate P, in order to cause the mist gas Msg to flow smoothly from the nozzle opening in the floor portion of the mist ejecting section 30 to the recovery opening in the floor portion of the mist recovering section 32. As made clear from the configuration of FIG. 1, the surface of the sheet substrate P moves in the +X direction while being exposed to the laminar flow of the mist gas Msg from the nozzle opening of the mist ejecting section 30 to the recovery opening of the mist recovering section 32. By adjusting the relationship between the movement velocity of the sheet substrate P caused by the feeding unit 5 and the flow velocity of the mist Msg flowing along the surface of the sheet substrate P, it is possible to change the thickness of the film made of nanoparticles (ITO or the like) ultimately deposited on the surface of the sheet substrate P. The material forming the chamber section 40 (air guide member 40A), the mist ejecting section 30, the mist recovering section 32, the droplet collecting sections 30T and 32T, and the like is preferably a resin material that is chemically stable, has excellent heat resistance and chemical resistance, has high electrical insulation, and has good workability. Fluororesin (fluorocarbon resin) such as Poly-Tetra-Fluoro-Ethylene (PTFE) made of fluorine atoms and carbon atoms is suitable as such a resin material.

In FIG. 1, with the ejection flow rate per unit time of the mist gas Msg from the nozzle opening of the mist ejecting section 30 being Qf (mL/sec) and the exhaust flow rate per unit time at the recovery opening of the mist recovering section 32 being Qv (mL/sec), these flow rates are preferably set to realize a relationship of Qf1≈Qv or Qf<Qv, and according to a fluid simulation, it is possible to recover almost all of the mist gas Msg sprayed inside the chamber section 40 if the exhaust flow rate Qv is set to be at least 1.5 times the ejection flow rate Qf. The balance between the ejection flow rate Qf and the exhaust flow rate Qv can be easily set by the flow rate adjusting valve 15 that controls the flow rate of the carrier gas CGS and by a flow rate adjustment of the depressurizing source of the mist gas collecting section 34 connected to the pipe 33.

Although not shown FIG. 1, it is possible to provide a processing unit that condenses the surface of the sheet substrate P, on the upstream side of the chamber section 40 (or the nip rollers 5E and 5F). Furthermore, it is possible to provide a drying unit that dries the thin liquid film (water film), having a thickness of approximately several micrometers to tens of micrometers and covering the surface of the sheet substrate P, immediately after mist deposition by the chamber section 40, on the downstream side of the chamber section 40.

In the present embodiment, a mist supplying section 31 is provided in order to improve the adhesion efficiency of the mist contained in the mist gas Msg to the sheet substrate P. The mist supplying section 31 supplies mist to the space between the surface of the sheet substrate P and the chamber section 40. This mist supplying section 31 includes the mist ejecting section 30 and a mist charging apparatus (charge providing section) 60 that provides a negative charge to the mist within the mist gas Msg supplied to the internal space of the mist ejecting section 30 via the pipe 17. Due to this, the mist ejecting section 30 can supply the mist charged by the mist charging apparatus 60 to the space between the surface of the sheet substrate P and the chamber section 40. Furthermore, in the present embodiment, an electrostatic field generating apparatus (electrostatic field generating section) 70 is provided that applies an electrostatic field in the Z direction to the space inside the chamber section 40, to cause the charged mist to efficiently adhere to the sheet substrate P. The mist charging apparatus 60 repeatedly applies a high-voltage pulse of several kilovolts or more between a pair of electrodes Ea and Eb arranged at the top portions of respective sidewalls of the mist ejecting section 30 facing each other in the X direction, to cause a discharge (corona discharge or the like) between the electrodes Ea and Eb and charge the mist with a negative charge. The electrostatic field generating apparatus 70 applies the negative electrode of an electrostatic field, via a wire 70a, to each of electrode plates Ec attached flat to the bottom portions of respective inner wall surfaces of the mist ejecting section 30 facing each other in the X direction and an electrode plate Ed attached flat to an inner wall surface (parallel to the XY plane) of the air guide member 40A of the chamber section 40. Furthermore, the electrostatic field generating apparatus 70 applies the positive electrode of the electrostatic field to a contact (brush) 71 that contacts a belt (made of steel) 5C at a position on the feeding apparatus roller 5A side.

The potential difference between the positive electrode and the negative electrode of the electrostatic field generating apparatus 70 is suitably adjusted in a range from several volts to hundreds of volts, according to the flow velocity of the mist gas Msg flowing inside the chamber section 40, the feeding velocity of the sheet substrate P, the type of mist solvent, the type of nanoparticles contained in the mist, the target thickness of the thin film formed by the nanoparticles, and the like. Since the mist contained in the mist gas Msg ejected from the nozzle opening of the mist ejecting section 30 is given a negative charge, the mist floating inside the chamber section 40 is given a force (repulsive force) away from the negative electrode plate Ed on the air guide member 40A side and a force (Coulomb force) toward the positive electrode plate 5C side. Since the belt 5C is firmly attached to the sheet substrate P, the mist carried by the mist gas Msg and flowing in the +X direction inside the chamber section 40 is deflected toward the surface of the sheet substrate P, thereby improving the adhesion efficiency of the mist to the surface of the sheet substrate P.

The only location where the charged mist receives a force (Coulomb force) in the −Z direction is in the space where the electrode plate Ed on the air guide member 40A side and the belt 5C face each other. Therefore, in a case where the X-direction distance from the nozzle opening of the mist ejecting section 30 to the recovery opening of the mist recovering section 32 is short, the X-direction length of the electrode plate Ed also becomes short, and when the flow velocity of the mist gas Msg is high, there are cases where a large amount of the mist is recovered by the mist recovering section 32 before effectively adhering to the sheet substrate P. In such a case, the potential difference applied between the electrode plate Ed and the belt 5C from the electrostatic field generating apparatus 70 should be increased. On the other hand, in a case where the flow velocity of the mist gas Msg flowing inside the chamber section 40 is low, a large amount of the mist adheres to the sheet substrate P, and therefore the liquid film (water film) covering the surface of the sheet substrate P becomes excessively thick (0.5 mm or more, for example), and the liquid (solvent) is caused to flow on the surface of the sheet substrate P. In such a case, the potential difference applied between the electrode plate Ed and the belt 5C from the electrostatic field generating apparatus 70 should be decreased. The absolute value of the potential difference applied from the electrostatic field generating apparatus 70 is preferably a constant DC voltage, and as an example, a zero potential (ground) may be set on the belt 5C side while a pulsed voltage (AC voltage) in which the absolute value of the voltage changes at a prescribed amplitude and a prescribed frequency centered on a neutral potential (average potential) of the negative electrode may be set on the electrode plate Ed side. In other words, the neutral potential (average potential) is an average value of the maximum value and minimum value of the potential of the pulsed voltage (AC voltage).

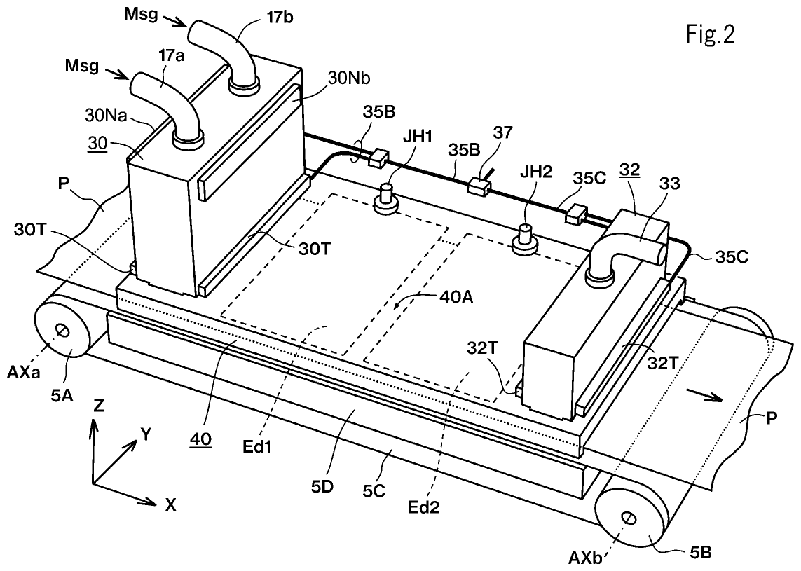

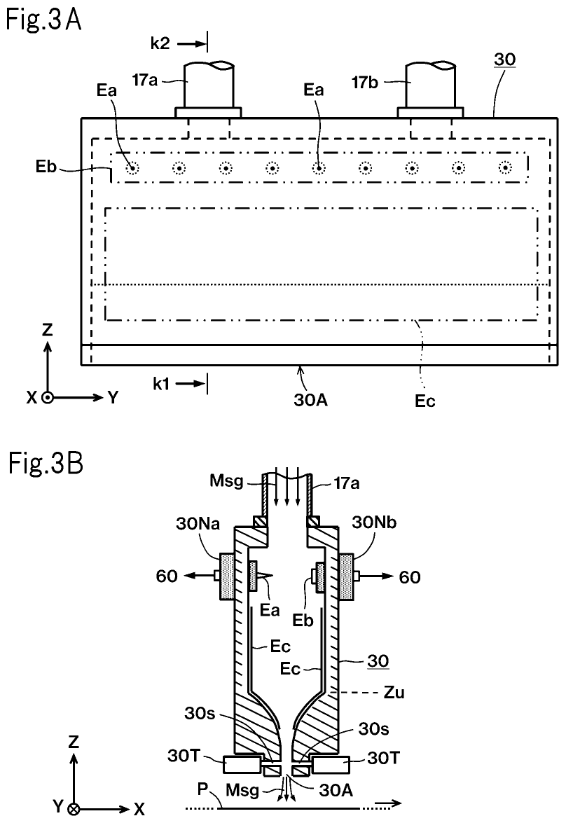

FIG. 2 is a perspective view of the arrangement of the depositing section formed by the mist ejecting section 30, the mist recovering section 32, and the chamber section 40 of the mist deposition apparatus MDE shown in FIG. 1, as seen from diagonally above; FIG. 3A is a front view of a configuration of the mist ejecting section 30 shown in FIGS. 1 and 2 in the YZ plane, as seen from the +X-direction side; and FIG. 3B is a cross-sectional view taken along the line k1-k2 of the mist ejecting section 30 of FIG. 3A. For each component in FIGS. 2, 3A, and 3B, components that are the same as those described in FIG. 1 are given the same reference symbols or numerals, and detailed descriptions thereof are omitted or simplified.

In FIG. 2, two pipes 17a and 17b corresponding to the pipe 17 shown in FIG. 1 are connected to the top portion of the mist ejecting section 30. The pipes 17a and 17b each branch the mist gas Msg generated from the one mist generating section 14 shown in FIG. 1 and supply the branched gas to the mist ejecting section 30, and the number of pipes 17 may be three or more. In this way, by arranging a plurality of pipes 17 at prescribed intervals in the Y direction of the mist ejecting section 30 and supplying the mist gas Msg to the internal space of the mist ejecting section 30, it is possible to restrict unevenness and realize uniformity for the flow rate distribution (or flow velocity distribution) of the mist gas Msg in the Y direction from a nozzle opening 30A shaped as a slit in the Y direction in the floor portion of the mist ejecting section 30 shown in FIGS. 3A and 3B. A mist generating section 14 may be provided independently corresponding to each of the two pipes 17a and 17b (or three or more pipes), in order to increase the total flow rate of the mist gas Msg.

In FIG. 2, among the electrodes to which the high voltage is applied from the mist charging apparatus 60 shown in FIG. 1, the electrode Ea is fixed to an insulating ceramic plate 30Na provided on the −X-direction-side inner surface of the mist ejecting section 30 shown in FIG. 3B, and the electrode Eb is fixed to an insulating ceramic plate 30Nb provided on the +X-direction-side inner surface of the mist ejecting section 30 shown in FIG. 3B. As shown in FIGS. 3A and 3B, in the present embodiment, a plurality of the electrodes Ea, each having a needle-shaped tip, are attached to the ceramic plate 30Na at constant intervals in the Y direction, and a plurality of the electrodes Eb, which are plate-shaped (or rod-shaped or linear) extending along the Y direction in which the plurality of needle-shaped electrodes Ea are lined up, are attached to the ceramic plate 30Nb.

As shown in FIG. 3B, when viewed in the XZ plane, the internal space of the mist ejecting section 30 is surrounded by internal wall surfaces facing each other across a certain interval in the X direction in a plane parallel to the YZ plane, from the top end portion (ceiling plate) to which the pipe 17 (pipe 17a) is connected to a height position Zu in the −Z direction. These opposing inner wall surfaces are formed such that the X-direction interval therebetween gradually decreases from the height position Zu until reaching the nozzle opening 30A in the floor portion of the mist ejecting section 30, and draw closer together until finally reaching an X-direction width of several millimeters or less at the position of the nozzle opening 30A. As shown in FIG. 3A, the electrode plates Ec shown in FIG. 1 are provided to each of the inner wall surfaces of the mist ejecting section 30 facing each other in the X direction, along almost the entire Y direction of the inner wall surfaces. The electrode plates Ec provide a repulsive force to the mist charged by the mist charging apparatus 60, and decrease the adhesion efficiency of the mist to the inner wall surfaces in the internal space. However, in a case where the inner wall surfaces of the mist ejecting section 30 are formed by a fluororesin (PTFE) with high liquid repellency, the electrode plates Ec can be omitted.

As shown in FIGS. 2 and 3B, droplet collecting sections 30T extending in the Y direction are provided respectively below the +X-direction and −X-direction outer walls of the mist ejecting section 30. The droplet collecting sections 30T are in communication with slots (grooves) 30s formed extending in the Y direction in the inner wall surfaces, slightly distanced in the +Z direction from the nozzle opening 30A in the floor portion of the mist ejecting section 30. The Z-direction thickness (groove width) of each slot 30s is set to be a thickness, 0.5 mm to 2 mm for example, with which droplets flowing along the inner wall surfaces of the mist ejecting section 30 can be sucked up by capillary action. Furthermore, the inner surface of each slot 30s is subjected to surface processing to be highly lyophilic (formation of a lyophilic coating film or the like). The droplet collecting sections 30T suck up the droplets stored inside the slots 30s at suitable intervals using the suction force from the small pump 37 shown in FIGS. 1 and 2, and send these droplets to the collection tank 36 via the tube 35B. The droplet collecting sections 32T extending in the Y direction are provided respectively below the +X-direction and −X-direction outer walls of the mist recovering section 32 shown in FIG. 2. Slots (grooves) extending in the Y direction are similarly formed in the inner wall surfaces of the mist recovering section 32 slightly in the +Z direction from the slit-shaped recovery opening in the floor portion of the mist recovering section 32, and the droplet collecting sections 32T suck up the droplets stored inside the slots 30s at suitable intervals using the suction force from the small pump 37 shown in FIGS. 1 and 2, and send these droplets to the collection tank 36 via the tube 35C.

As shown in FIG. 1, the flat electrode plate Ed is provided on the inner wall surface (parallel to the XY plane) of the air guide member 40A of the chamber section 40, but in FIG. 2, the electrode plate Ed is shown as being split into two electrode plates Ed1 and Ed2 in the feeding direction of the sheet substrate P (X direction). The electrode plate Ed1 arranged on the upstream side in the feeding direction of the sheet substrate P is electrically connected to a connection terminal JH1 provided protruding on the upper outer wall surface of the air guide member 40A, and the connection terminal JH1 is connected to the wire 70a on the negative electrode side of the electrostatic field generating apparatus 70 in FIG. 1. Similarly, the electrode plate Ed2 arranged on the downstream side in the feeding direction of the sheet substrate P is electrically connected to a connection terminal JH2 provided protruding on the upper outer wall surface of the air guide member 40A, and the connection terminal JH2 is connected to the wire 70a on the negative electrode side of the electrostatic field generating apparatus 70.

As shown in FIG. 2, in a case where the electrode plate Ed is divided in the feeding path between the mist ejecting section 30 and the mist recovering section 32 inside the chamber section 40, it is possible to adjust the negative voltage applied to the electrode plate Edl on the upstream side and the negative voltage applied to the electrode plate Ed2 on the downstream side to be different values. Therefore, a configuration should be used in which a variable resistor is provided between the positive electrode and the negative electrode at the voltage output stage of the electrostatic field generating apparatus 70, a voltage (negative polarity) divided by the variable resistor is applied to one of the electrode plates Edl and Ed2, and the voltage (negative voltage) prior to division is applied to the other electrode plate Edl or Ed2. In this way, the negative potentials applied respectively to the electrode plates Edl and Ed2 are caused to be different respectively on the upstream side and the downstream side in the feeding direction of the sheet substrate P, thereby making it possible to adjust the degree of adhesion efficiency of the mist to the surface of the sheet substrate P over time. It should be noted that the splitting of the electrode plate Ed may be performed to create three or more electrode plates Ed along the feeding direction of the sheet substrate P through the inside of the chamber section 40, and each electrode plate resulting from the splitting may be set to have a different negative potential from the others.

### [First Modification]

In the first embodiment described above, a configuration is used in which, during the mist deposition, the sheet substrate P is supported on the belt 5C that moves horizontally, and the mist gas Msg is sprayed with the surface of the sheet substrate P being in a horizontal state (state parallel to the XY plane). In this way, in the case of a configuration in which the sheet substrate P is supported by the belt 5C, the sheet substrate P can be single sheet substrates having fixed vertical and horizontal dimensions, such as the A4 type, A3 type, or B4 type, for example. However, in a case where mist deposition for sheet substrates having a length of tens of meters to hundreds of meters is performed continuously using a roll-to-roll technique in a state realizing a stable film thickness, there is a concern that wrinkles will occur due to vacuum suction of the sheet substrates onto the belt 5C or the like, and therefore there is an idea to use a feeding mechanism that continuously moves the sheet substrate while closely supporting a portion of the sheet substrate in the length direction on the outer circumferential surface of a rotating drum.

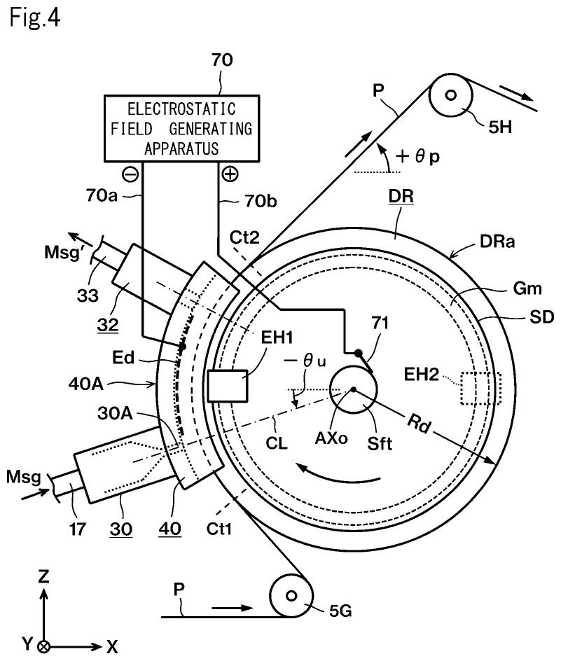

FIG. 4 shows a schematic modified configuration of the mist depositing section in the mist depositing apparatus using a feeding mechanism (feeding section) made of a rotating drum. The orthogonal coordinate system XYZ of FIG. 4 is set such that the Z direction is the vertical direction (direction of gravity) and the XY plane is the horizontal plane, in the same manner as the coordinate system XYZ in each of the FIGS. 1 to 3B above. Furthermore, components shown in FIG. 4 that are the same as or have functions equivalent to components shown in FIGS. 1 to 3B above or are given the same reference numerals.

In FIG. 4, a metal rotating drum DR made of steel or aluminum rotates on a center line AXo parallel to the Y-axis, and has an outer peripheral surface DRa with a constant radius Rd from the center line AXo. The Y-direction length of the outer circumferential surface DRa is set to be slightly longer than the width that is the transverse direction (Y direction) of the long sheet substrate P, and the radius Rd can be set relatively freely despite also depending on the width, and can be set in a range of 5 cm≤Rd≤50 cm, for example. A metal shaft Sft that is coaxial with the center line AXo is provided at both Y-direction ends of the rotating drum DR. The shaft Sft is attached to a body frame (case) of the mist depositing apparatus MDE, and is connected to a torque shaft of a rotational drive source (motor or decelerator) (not shown in the drawings) to rotate the rotating drum DR at a prescribed angular velocity. A scale disc SD for encoder measurement is fixed coaxially with the center line AXo to the shaft Sft separated in the Y direction from a Y-direction end portion of the rotating drum DR. A scale Gm that can be read by an encoder head EH1 is engraved in a ring-band shape in the circumferential direction in a constant radial region from the center line AXo, on a side surface of the scale disc SD perpendicular to the center line AXo (surface parallel to the XZ plane). The encoder head EH1 is arranged facing the side surface (parallel to the XZ plane) of the scale disc SD, optically detects positional change of a grid of the scale Gm (for example, a diffraction grating engraved with a pitch of 20 μm in the circumferential direction) that moves in the circumferential direction in response to clockwise rotation of the rotating drum DR, and is used to measure the movement amount of the outer drum surface DRa in the circumferential direction or the movement velocity of the outer drum surface DRa in the circumferential direction from a rotational angle position of the rotating drum DR.

The sheet substrate P is folded back by a roller 5G, which has a rotational shaft parallel to the center line AXo and is arranged below the rotating drum DR, a constant tension is applied to a portion of the outer circumferential surface DRa of the rotating drum DR, and the substrate P is wound while being supported in an arc shape, after which the sheet substrate P is passed on to a roller 5H, which has a rotational shaft parallel to the center line AXo and is arranged above the rotating drum DR, to be fed in the longitudinal direction. At this time, the sheet substrate P firmly contacts the outer circumferential surface DRa across a range of approximately 90 degrees from an angle position (entry position) Ct1 to an angle position (exit position) Ct2 in the circumferential direction of the rotating drum DR. The mist depositing section formed by the mist ejecting section 30, the mist recovering section 32, and the chamber section 40 is arranged curved in the circumferential direction within the angle range between the entry position Ct1 and the exit position Ct2 on the outer circumferential surface DRa of the rotating drum DR.

As shown in FIG. 4, the chamber section 40 includes the air guide member 40A that is curved in a manner to form a constant interval space from the outer circumferential surface DRa or the surface of the sheet substrate P, along the radial direction of the rotating drum DR. The mist ejecting section 30 is arranged on the upstream side of the air guide member 40A in the feeding direction of the sheet substrate P, such that an ejection direction (direction of the line CL) of the mist gas Msg sprayed from the nozzle opening 30A of the mist ejecting section 30 is inclined by an angle −θu relative to the horizontal plane (XY plane). By pointing the nozzle opening 30A of the mist ejecting section 30 diagonally upward in this manner, droplets caused by the mist adhering to and aggregating on the inner surface walls of the mist ejecting section 30 are prevented from dripping along the inner surface walls and onto the sheet substrate P from the nozzle opening 30A. The mist gas Msg ejected from the nozzle opening 30A flows in the circumferential direction of the outer circumferential surface DRa of the rotating drum DR through the space between the curved inner wall surface of the air guide member 40A facing the sheet substrate P and the surface of the sheet substrate P, and the surplus mist gas Msg′ is recovered by the mist recovering section 32.

The electrode plate Ed, which is connected to the wire 70a on the negative electrode side of the electrostatic field generating apparatus 70, is attached in a curving manner on the curved inner wall surface of the air guide member 40A, and the contact 71 that contacts the shaft Sft of the rotating drum DR is connected to the positive electrode of the electrostatic field generating apparatus 70 via a wire 70b. Due to this, an electrostatic field attracting the mist to the sheet substrate P side is formed between the curved electrode plate Ed and the outer circumferential surface DRa of the rotating drum DR.

The thin liquid film is formed by mist deposition on the entire surface of the sheet substrate P after the sheet substrate P has passed through the chamber section 40, and the sheet substrate P is fed from the exit position Ct2 toward a roller 5H in a state of being inclined upward by an angle +θp relative to the horizontal plane (XY plane). The solution (solvent) on the surface of the sheet substrate P is dried (evaporated) during the transport from the exit position Ct2 to the roller 5H to form the deposited film (conductive film) made of the nanoparticles that were contained in the mist on the surface of the sheet substrate P. The distance L from the exit position Ct2 to the roller 5H is set according to the product (L=Vp·Tv) of the feeding velocity Vp of the sheet substrate P (rotational velocity of the rotating drum DR) and the time Tv until completion of the drying (evaporating) of the liquid film covering the surface of the sheet substrate P immediately after mist deposition. It should be noted that a mechanism may be prepared in advance in which the position of the roller 5H in the Z direction and X direction can be changed, such that the inclination angle +θp of the sheet substrate P from the exit position Ct2 to the roller 5H can be adjusted in a range from 0°≤θp≤50°, according to the type of mist solvent (liquid film).

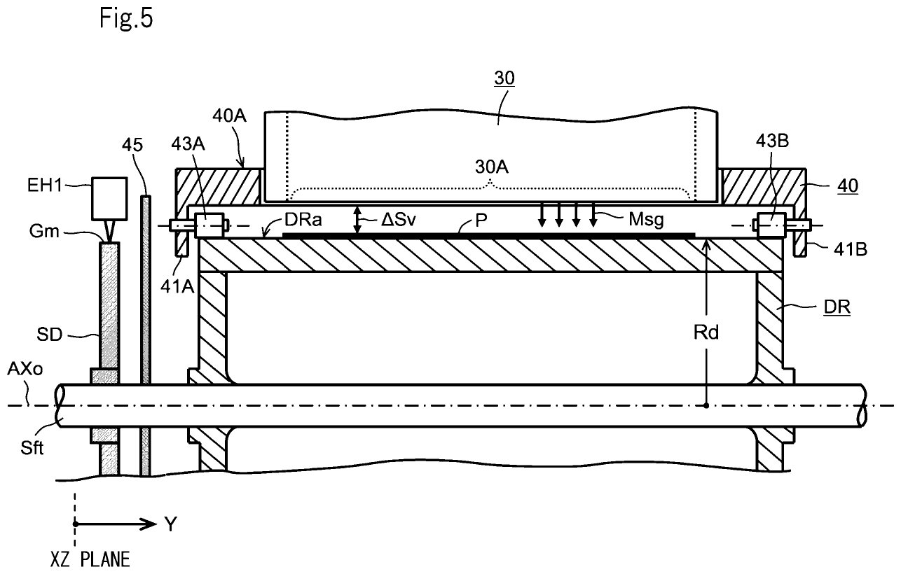

The encoder head EH1 is arranged facing the scale Gm of the scale disc SP in a manner to be positioned in the same direction as the chamber section 40 or the same direction as the nozzle opening 30A of the mist ejecting section 30, as seen from the center line AXo. Therefore, in a case where mist gas Msg has leaked from the gap between the chamber section 40 and the outer circumferential surface DRa of the rotating drum DR, there is a possibility of this mist gas Msg adhering to optical components or the like inside the encoder head EH1 and causing problems (decrease in signal strength or the like) with the reading of the scale Gm. In such a case, as shown by the dashed line in FIG. 4, the encoder head EH2 can be arranged in a direction having point symmetry (a position rotated by approximately 180 degrees) relative to the encoder head EH1 with regard to the central axis AXo, that is, the encoder head EH2 can be arranged at the position farthest from the chamber section 40. In the configuration shown in FIG. 4, the encoder heads EH1 and EH2 are arranged facing a side surface of the scale disc SD that is perpendicular to the center line AXo, but in a case where the scale Gm is formed along an outer circumferential surface of the scale disc SD that is parallel to the center line AXo, the arrangement of the encoder head EH1 (or encoder head EH2) and the scale disc SD may be set as in the second modification, as shown in FIG. 5.

### [Second Modification]

FIG. 5 is a partial cross-sectional view when the rotating drum DR and the chamber section 40 are cleaved by a plane that includes the line CL and the center line AXo shown in FIG. 4 and passes through the nozzle opening 30A of the mist ejecting section 30. In FIG. 5, the rotating drum DR has a hollow structure in order to be lightweight, and the shaft Sft is provided in a manner to penetrate through both Y-direction ends of the rotating drum DR. The sheet substrate P is firmly supported by the outer circumferential surface DRa with the radius Rd of the rotating drum DR. The scale disc SD of the encoder measurement system is fixed coaxially with the shaft Sft to the Y-direction side of the rotating drum DR. The radius of the scale disc SD of FIG. 5 is set to be approximately the same as the radius Rd of the rotating drum DR (radius that is ±10% relative to the radius Rd), and the scale Gm is formed on the outer circumferential surface of the scale disc SD. Therefore, the encoder head EH1 (or EH2) is arranged in the radial direction of the scale disc SD in a manner to face the scale Gm.

The inner wall surface of the air guide member 40A of the chamber section 40 is arranged to be curved in the circumferential direction along the outer circumferential surface DRa of the rotating drum DR, in a manner to form a space with a constant interval ΔSv (several millimeters to tens of millimeters) in the radial direction from the surface of the sheet substrate P. The mist Msg from the nozzle opening 30A of the mist ejecting section 30 flows in the circumferential direction through the space of the interval ΔSv, after being ejected in a direction normal to the surface of the sheet substrate P. In the present modification, in order to suppress leaking of the mist gas Msg in the Y direction (toward the encoder head EH1 side) from the space of the interval ΔSv, flange portions (skirts) 41A and 41B extending in the radial direction are provided at the Y-direction end portions of the air guide member 40A. The flange portions 41A and 41B are formed with fan shapes when viewed in the YZ plane perpendicular to the center line AXo, and are formed such that the distance of the tip positions of the flange portions 41A and 41B on the shaft Sft side from the center line AXo is less than the radius Rd of the rotating drum DR. Furthermore, the intervals between the Y-direction end surfaces of the rotating drum DR and the respective flange portions 41A and 41B are set to be small gaps of approximately one millimeter to several millimeters, for example.

Due to this, the mist gas Msg that leaks toward the outside of the chamber section 40 (Y direction) from the space of the interval ΔSv flows in a direction toward the shaft Sft (radial direction) from the gaps between the flange portions 41A and 41B and the Y-direction side surface ends of the rotating drum DR, and is prevented from being sprayed near the encoder head EH1. Furthermore, in the present embodiment, a disc-shaped air blocking plate 45 is provided coaxially with the shaft Sft, between the scale disc SD and the −Y-direction side end surface of the rotating drum DR. The radius of the air blocking plate 45 from the center line AXo is set to be greater than the radius Rd of the rotating drum DR (or the radius of the scale disc SD), and is preferably set to a radius that covers the distance in the radial direction from the center line AXo to the encoder head EH1, as shown in FIG. 5. Due to this, the mist gas Msg that has leaked from the flange portion 41A, in the direction from the space of the interval ΔSv the outside of the chamber section 40 (Y direction), is prevented from being sprayed onto the scale Gm of the scale disc SD. If spraying of the leaked mist gas Msg onto the encoder head EH1 or the scale Gm of the scale disc SD is sufficiently prevented, it is possible to omit either the flange portion 41A or the air blocking plate 45.

Furthermore, in the present modification, in order to keep the interval ΔSv in the radial direction between the curved inner wall surface of the air guide member 40A attached to the chamber section 40 (or the tip of the nozzle opening 30A of the mist ejecting section 30) and the sheet substrate P constant, rotating bodies (bearings) 43A and 43B, which rotate freely and contact the Y-direction end portions of the outer circumferential surface DRa of the rotating drum DR, are attached to the inner sides (rotating drum DR sides) of the respective flange portions 41A and 41B such that the rotational shafts thereof are arranged parallel to the center line AXo. When viewed in the XZ plane, two rotating bodies 43A are provided respectively at two locations distanced from each other in the circumferential direction of the fan-shaped flange portion 41A, and similarly, when viewed in the XZ plane, two rotating bodies 43B are provided respectively at two locations distanced from each other in the circumferential direction of the fan-shaped flange portion 41B. The chamber section 40 is arranged on the −X-direction side of the rotating drum DR, as shown in FIG. 4, and therefore the rotating bodies 43A and 43B at the total of four locations are always biased in the +X direction in a manner to contact the outer circumferential surface DRa of the rotating drum DR. Each of the rotating bodies 43A and 43B provided respectively at the four locations may be an air pad that ejects gas in a manner to form an air bearing (static pressure gas layer) between itself and the outer circumferential surface DRa.

According to the first embodiment, the first modification, and the second modification described above, by providing the mist generating section 14 as a mist generating mechanism that atomizes the solution Lq containing the material nanoparticles and sends out the mist gas Msg containing the generated mist; the mist ejecting section 30 as a mist ejecting mechanism that allows the mist gas Msg to flow therein and ejects the mist toward the sheet substrate P serving as a processing target substrate; the chamber section 40 as an air guide mechanism formed by an air guide member 40A having an inner wall surface facing the surface of the sheet substrate P with a prescribed interval (ΔSv) therebetween, in order to cause the mist gas Msg from the mist ejecting section 30 to flow along the surface of the sheet substrate P; and an electrostatic field generating apparatus 70 that serves as a mist guidance mechanism, which generates a repulsive force (repellent force) between the mist and an inner wall surface of the air guide member 40A of the chamber section 40 in order to generate an attractive force that attracts the mist to the surface of the sheet substrate P, and generates an electrostatic field between the belt 5C (or rotating drum DR) supporting the sheet substrate P and the electrode plate Ed arranged on the air guide member 40A, it is possible to realize a mist deposition apparatus that improves the adhesion of the mist to the surface of the sheet substrate P and improve the deposition efficiency of the film layer formed by depositing minute particles of the material substance.

### Second Embodiment

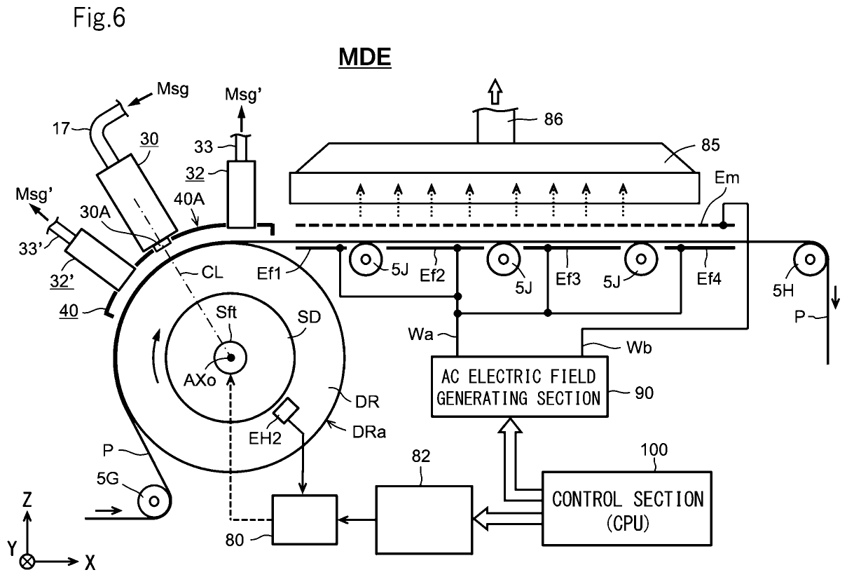

FIG. 6 is a schematic view showing an overall configuration of the mist deposition apparatus MDE according to a second embodiment, and the orthogonal coordinate system XYZ is set such that the Z direction is the direction of gravity, in the same manner as in FIG. 1. In the same manner as in FIG. 4 above, the mist deposition apparatus MDE of FIG. 6 is configured to perform mist deposition on the rotating drum DR while transporting the long sheet substrate P in the longitudinal direction using the rotation of the rotating drum DR supporting the sheet substrate P in a flat cylindrical state. Furthermore, in the mist deposition apparatus MDE of FIG. 6, the components and configurations having the same function as components and configurations shown in any of FIGS. 1 to 4 above are given the same reference numerals, and descriptions thereof are omitted or simplified. In the present embodiment, before the solvent (pure water or the like) of the thin liquid film formed on the surface of the sheet substrate P by the mist deposition is dried, the nanoparticles contained in the liquid film are oscillated with an electric force to smooth the uneven thickness distribution of the nanoparticles deposited on the surface of the sheet substrate P.

In FIG. 6, the sheet substrate P is hung around the conductive outer circumferential surface DRa of the rotating drum DR via the roller 5G and the mist deposition is performed below the chamber section 40 that includes the mist ejecting section 30 and the mist recovering section 32, after which the sheet substrate P is fed approximately horizontally in the +X direction from the +Z-direction top end portion of the outer circumferential surface DRa of the rotating drum DR, while being kept at a constant tension. The sheet substrate P that is fed horizontally is supported by a plurality of rollers 5J lined up in the feeding direction (X direction), and is bent downward (−Z direction) by the final roller 5H. In the present embodiment, a process of drying the liquid film (solvent of pure water or the like) formed by the mist deposition on the surface of the sheet substrate P is applied in the horizontal feeding path of the sheet substrate P supported by the plurality of rollers 5J. In order to realize this drying process, an exhaust drying section (drying section) 85, which sucks up gas (air) near the surface of the horizontally fed sheet substrate P via an exhaust duct 86, is arranged above the horizontal feeding path formed by the plurality of rollers 5J. Furthermore, to the chamber section 40 forming the mist depositing section of the present embodiment, a mist recovering section 32′ similar to the mist recovering section 32 is attached not only on the downstream side of the mist ejecting section 30 but also the upstream side in the bent feeding direction of the sheet substrate P, and the surplus mist gas Msg′ flowing out from the mist ejecting section 30 to the upstream side is collected by the mist gas collecting section 34 shown in FIG. 1 via a pipe 33′. The ejection direction of the mist gas Msg from the nozzle opening 30A of the mist ejecting section 30 of the present embodiment is set to be inclined in a range of 0° to −90° (preferably −45°) relative to a plane containing the central axis AXo and parallel to the YZ plane as shown by the line CL in FIG. 6, when viewed in the XZ plane.

The rotating drum DR is rotated by a motor contained in a rotational drive source 80 connected to the shaft Sft, and the rotational drive source 80 performs servo control of the motor such that the outer circumferential surface DRa of the rotating drum DR (sheet substrate P) is moved with high precision at an instructed circumferential velocity, based on instruction information from a drive circuit 82 and velocity information measured by the detection signal from the encoder head EH2 reading the scale Gm of the scale disc SD. The instruction information provided to the drive circuit 82 is created by a control section (CPU) 100 that performs integrated control of the overall apparatus.

Furthermore, in the present embodiment, a plurality of electrode plates Ef1 to Ef4 are arranged parallel to the sheet substrate P respectively between the plurality of rollers 5J in the X direction, on the back surface side (−Z-direction side) of the sheet substrate P moving along the horizontal feeding path after exiting the rotating drum DR. The electrode plates Ef1 to Ef4 are arranged at a constant interval (several millimeters or more, for example) from the back surface of the sheet substrate P. Furthermore, mesh electrode plates (mesh electrodes) Em having a surface area covering all of the electrode plates Ef1 to Ef4 are arranged parallel to the sheet substrate P between the sheet substrate P and the exhaust drying section 85, at the top surface side (+Z-direction side) of the sheet substrate P moving along the horizontal feeding path after exiting the rotating drum DR. The electrode plates Em are arranged at a constant interval (several millimeters or more, for example) from the top surface of the sheet substrate P. The interval (inter-electrode gap) in the Z direction between the electrode plates Em and the electrode plates Ef1 to Ef4 is set to be approximately constant across the X direction, and is in a range from 10 mm to 30 mm, for example. An AC potential from an AC electric field generating section 90 is applied between the electrode plates Ef1 to Ef4 and the electrode plates Em, via wires Wa and Wb. This AC potential is set according to the instructions from the control section 100.

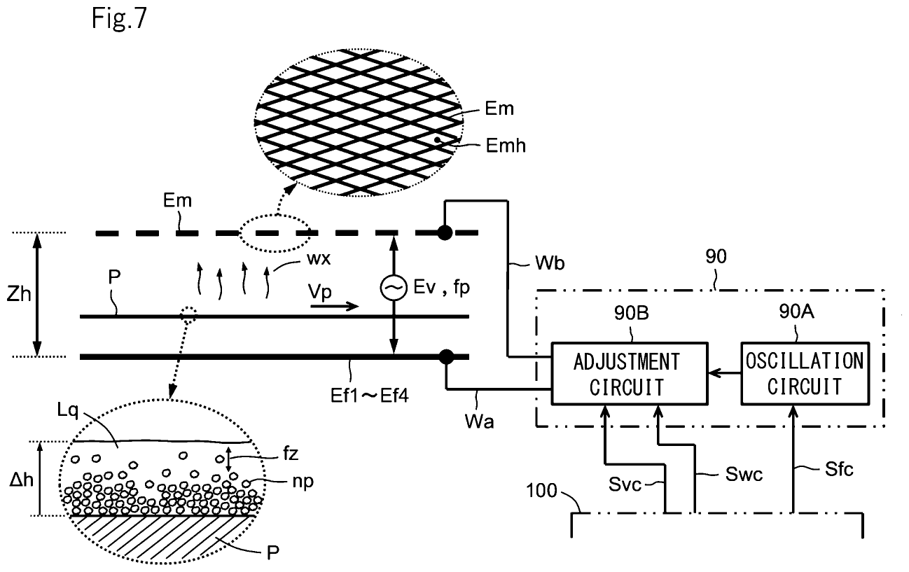

FIG. 7 shows a detailed configuration of a nanoparticle deposition smoothing section (also referred to as a nanoparticle oscillating section or electrophoresis applying section) formed by the AC electric field generating section 90 and the electrode plates Em and electrode plates Ef1 to Ef4 of FIG. 6. In FIG. 7, components that are the same as components shown in FIG. 6 are given the same reference numerals. The electrode plates Em are formed by opening a matrix of innumerable openings Emh in a stainless steel plate to form a mesh shape of thin linear portions. The electrode plates Ef1 to Ef4 are also formed of stainless steel plates, and the intervals between the electrode plates Em in the Z direction are Zh. The AC electric field generating section 90 includes an oscillation circuit 90A that generates an AC signal (sine wave) at a frequency fp corresponding to instruction information Sfc from the control section 100, and an adjustment circuit 90B that transforms the waveform of the AC signal (sine wave) according to instruction information Swc from the control section 100, adjusts the amplitude of the AC signal according to instruction information Svc, and applies the resulting AC signal to the wires Wa and Wb. The AC voltage Ev at the frequency fp applied between the electrode plates Em and the electrode plates Ef1 to Ef4 is the peak amplitude value or the effective amplitude value.

As shown in FIG. 7, while the sheet substrate P is moving in the +X direction at the velocity Vp, an evaporation component wx is generated according to the drying of the solvent (pure water or the like) from the liquid film (referred to here as Lq for convenience) made of the solvent Lq having the thickness Δh formed on the surface (top surface) of the sheet substrate P, and this evaporation component wx passes through the openings Emh of the mesh electrode plates Em to be sucked in by the exhaust drying section 85. In the liquid film Lq, innumerable nanoparticles np are present in a state of being deposited on the surface of the sheet substrate P or in a floating state. In this state, when the AC electric field whose strength changes in the Z direction is applied with a frequency fp to the liquid film Lq by the AC electric field generating section 90, the nanoparticles np vibrate with an electrophoretic force fz corresponding to the strength of the AC electric field, thereby improving the unevenness of the deposition state and smoothing the film thickness distribution realized by the deposition of the nanoparticles np. The electric field caused by the AC voltage Ev is preferably continued until the liquid film Lq on the surface of the sheet substrate P is mostly dry.

Therefore, with the drying time until the liquid film Lq on the surface of the sheet substrate P is mostly dry being Tvp, the X-direction length HGx of the electric field space between the electrode plates Em and the electrode plates Ef1 to Ef4 should be set from the velocity Vp of the sheet substrate P such that HGx≥Tvp·Vp. Furthermore, the drying time Tvp of the liquid film Lq changes according to the temperature of the sheet substrate P, the temperature and humidity of the surrounding environment, the wind speed of the surrounding gas contacting the sheet substrate P, and the like, but in order to shorten the drying time Tvp even a small amount, a heater may be provided to set the temperature of the electrode plates Ef1 to Ef4 arranged on the back surface side of the substrate P to a value higher than room temperature (24° C.), for example a temperature from tens of degrees Celsius to 100 degrees Celsius.

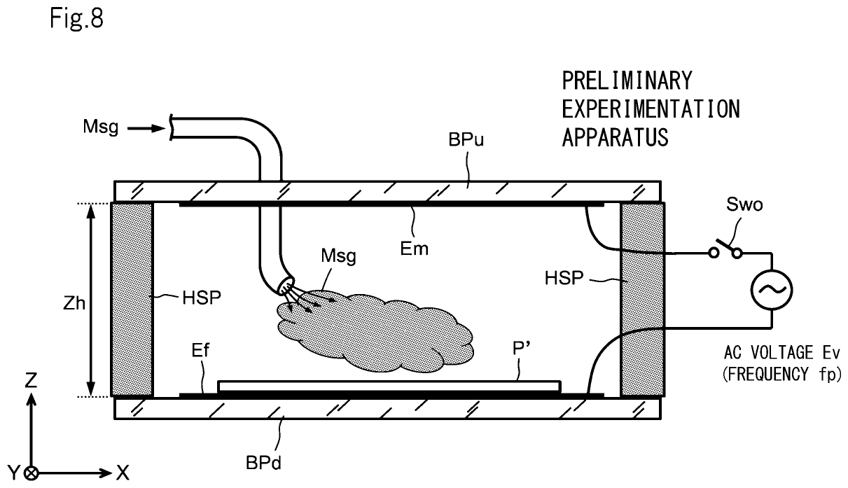

It was confirmed through preliminary experimentation that by applying the AC electric field before the liquid film Lq of the sheet substrate P is dried in the manner described above, it is possible to improve the state of the film made of nanoparticles ultimately formed on the sheet substrate P. FIG. 8 shows a configuration of a preliminary experimentation apparatus for checking how the deposition state of the thin film made of nanoparticles changes by applying an AC electric field to the liquid film Lq. In the orthogonal coordinate system XYZ of FIG. 8, the Z direction is the direction of gravity and the XY plane orthogonal to the Z direction is the horizontal plane. In the preliminary experimentation apparatus, a 50 mm square glass substrate P′ is used as a sample onto which the mist gas Msg is sprayed for a certain time. The glass substrate P′ is placed on a conductive film formed as an electrode plate Ef on the top surface of an insulating floor plate BPd, and support pillars HSP having a height Zh in the Z direction are provided respectively at both X-direction sides of the floor plate BPd. An insulating ceiling plate BPu is placed on the top portions of the support pillars HSP in a manner to be parallel to the floor plate BPd. A conductive film is formed as the electrode plate Em on the bottom surface of the ceiling plate BPu. The AC voltage Ev (frequency fp) having a sine wave shape is applied, via a switch Swo, between the respective conductive films serving as the electrode plate Ef and the electrode plate Em.

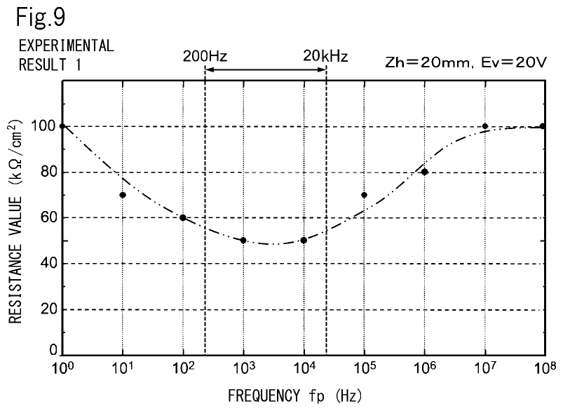

In a Preliminary Experiment 1, first, using a solvent Lq containing a prescribed concentration (10 wt. %, for example) of ITO nanoparticles with particle diameters of 30 nm to 50 nm (average particle size 40 nm) for the mist gas Msg, a liquid film Lq was formed by spraying this mist gas Msg onto the surface of the glass substrate P′ placed on the floor plate BPd for a certain time, after which an investigation was made concerning what resistance changes occur in a thin film of the deposited ITO nanoparticles due to the frequency fp of the AC voltage Ev applied while the liquid film Lq is being dried. FIG. 9 is a graph showing Experiment Result 1 of Preliminary Experiment 1 with the frequency fp (Hz) of the AC voltage Ev on the horizontal axis and the resistance value (kΩ/cm²) of the ITO nanoparticle thin film on the vertical axis. In Preliminary Experiment 1, the electrode interval (support pillar HSP height) Zh between the electrode plate Ef and the electrode plate Em was kept at 20 mm and the AC voltage Ev (effective value) was set to 20 V (that is , the AC electric field strength is set to an effective value of 1 V/mm), the glass substrate P′ was replaced and a liquid film Lq was formed thereon, after which the resistance values of ITO nanoparticles deposited under respective AC electric fields having frequencies fp of 1 Hz, 10 Hz, 100 Hz, 1 kHz, 10 kHz, 100 kHz, 1 MHz, 10 MHz, and 100 MHz were measured.

As shown in FIG. 9, in the case of the ITO nanoparticles used in Preliminary Experiment 1, it was found that the resistance value of the thin film made of ITO nanoparticles decreases by approximately half when the frequency fp was from 200 Hz to 20 kHz. In FIG. 9, the highest resistance value obtained with an electric field having a frequency fp of 0 Hz (no electric field applied) or greater than or equal to 10 MHz was approximately 100 kQ/cm². The decrease in the resistance value caused by the application of electric field is thought to be because, since the ITO nanoparticles in the liquid film Lq vibrate due to having polarity, localized roughness in the direction along the surface of the ITO particles deposited on the surface of the glass substrate P′ is alleviated, the contact paths (conduction paths) among the ITO nanoparticles in the surface increase, and the average conductivity of the ITO nanoparticle thin film increases.

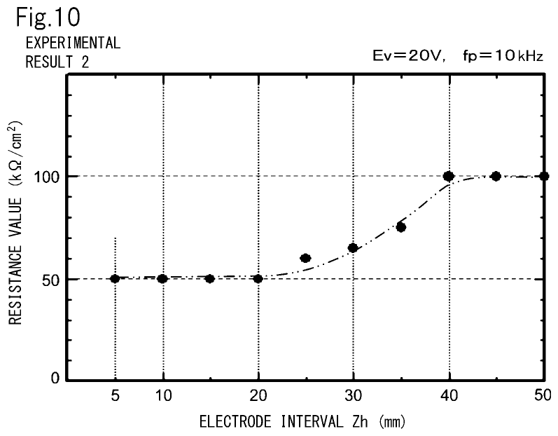

Next, as Preliminary Experiment 2, the AC voltage Ev was set to 20 V, the frequency fp was set to 10 kHz, and an investigation was performed concerning the resistance value change of the thin film made of ITO nanoparticles (average particle size of 40 nm) at each 5 mm interval in a range of 5 mm to 50 mm for the electrode interval Zh. FIG. 10 is a graph of Experimental Result 2 of Preliminary Experiment 2 in which the electrode interval Zh (mm) is on the horizontal axis and the resistance value (kΩ/cm²) of the ITO nanoparticle thin film is on the vertical axis. In Preliminary Experiment 2, the frequency fp of the AC electric field was set to 10 kHz, which realizes the lowest resistance value, based on the findings obtained in Preliminary Experiment 1. As shown in FIG. 10, in Preliminary Experiment 2, a decrease in the resistance value at electrode intervals Zh greater than or equal to 40 mm was not observed, the resistance value gradually decreased as the electrode interval Zh narrowed from 40 mm to 20 mm, and the resistance value became approximately constant at electrode intervals Zh less than or equal to 20 mm. Based on Preliminary Experiment 2, it is determined that, in the case of the ITO nanoparticles used in the experiment, the strength of the AC electric field applied during drying of the liquid film Lq is greater than or equal to 0.5 V/mm (20V/40 mm) and preferably greater than or equal to 1 V/mm at an effective value.

Furthermore, as Preliminary Experiment 3, the AC voltage Ev was set to 20 V, the electrode interval Zh was set to 20 mm, and an investigation was made concerning the dependency on the frequency fp for extremely small ITO nanoparticles with an average particle size of 10 nm, as a comparison to the ITO nanoparticles with an average particle size of 40 nm used in Preliminary Experiments 1 and 2. In Preliminary Experiment 3, the electrode interval Zh was kept at 20 mm and the AC voltage Ev (effective value) was set to 20 V, the glass substrate P′ was replaced and a liquid film Lq was formed thereon, after which the resistance values of ITO nanoparticles with an average particle size of 10 nm deposited under respective AC electric fields having frequencies fp of 1 Hz, 10 Hz, 100 Hz, 1 kHz, 10 kHz, 100 kHz, 1 MHz, and 10 MHz were measured.

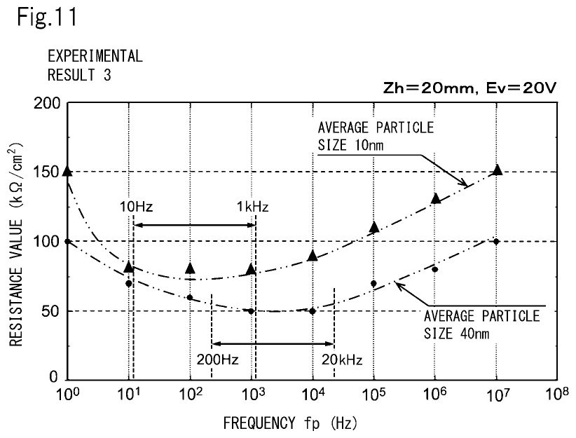

FIG. 11 is a graph showing Experiment Result 3 of Preliminary Experiment 3 with the frequency fp (Hz) of the AC voltage Ev on the horizontal axis and the resistance value (kΩ/cm²) of the ITO nanoparticle thin film on the vertical axis. As shown in FIG. 11, in the case of the ITO nanoparticles having an average particle size of 10 nm used in Preliminary Experiment 3, it was determined that the resistance value of the thin film made of ITO nanoparticles decreases by approximately half when the frequency fp is from 10 Hz to 1 kHz. In FIG. 11, with an electric field having a frequency fp of 0 Hz (no electric field applied) or greater than or equal to 10 MHz applied, the highest resistance value of the thin film made of ITO nanoparticles with an average particle size of 40 nm obtained was approximately 100 kΩ/cm² (same as Preliminary Experiment 1 above), and the highest resistance value of the thin film made of ITO nanoparticles with an average particle size of 10 nm obtained was approximately 150 kΩ/cm². From Preliminary Experiment 3, it was determined that even for nanoparticles made of the same material, a difference in particle size causes a difference in the frequency range of the AC electric field caused by the electrophoretic force fz.

The electrode interval Zh between the electrode plates Ef1 to Ef4 and the electrode plate Em of the mist deposition apparatus MDE shown in FIGS. 6 and 7 and the frequency fp and effective value of the AC electric field Ev applied between the electrodes by the AC electric field generating section 90 are set based on the findings of the preliminary tests described above. The optimal values for the interval Zh, the AC voltage Ev, and the frequency fp differ according to the type of the solvent Lq, the type and particle size of the nanoparticles, and the like, and therefore are determined by the preliminary experimentation apparatus such as shown in FIG. 8 or the like. One cause of the electrophoretic force fz occurring in the nanoparticles in the liquid film Lq is believed to be because the nanoparticles have polarity.

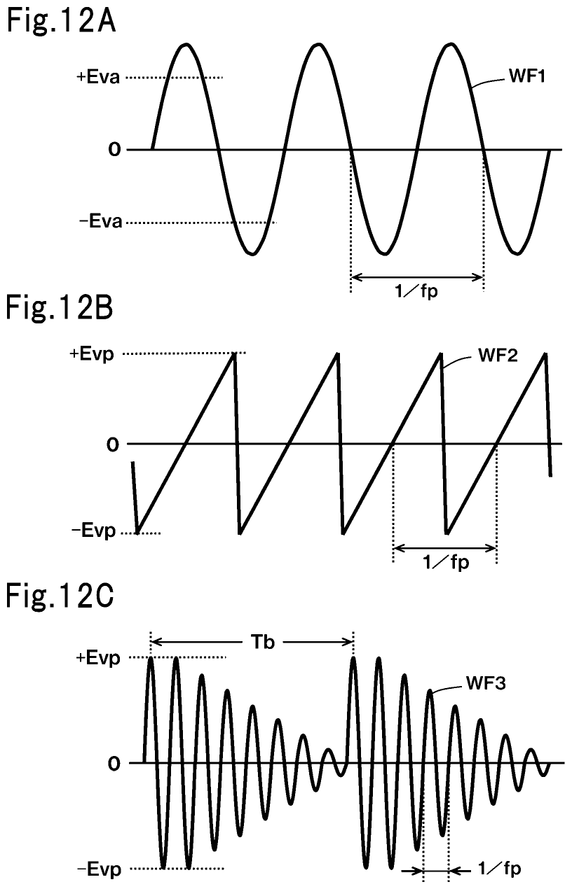

It should be noted that the waveform of the AC voltage Ev applied between the electrode plates Ef1 to Ef4 and the electrode plate Em can be transformed such as shown in FIGS. 12A to 12C by the AC electric field generating section 90 of the mist deposition apparatus MDE shown in FIGS. 6 and 7. FIG. 12A is a typical sine wave WF1 for the AC voltage, and the characteristics thereof are represented by the frequency fp and the effective value Eva (1/[2^{0.5}] of the peak value). FIG. 12B is a sawtooth wave WF2 with a peak value of ±Evp, and FIG. 12C is a burst waveform WF3 obtained by attenuating a sine wave having the frequency fp with amplitude modulation every time Tb (Tb>1/fp). As another waveform of the AC electric field, there may be a square waveform in which the duty ratio (ratio of the high level continuation time contained in one period of 1/fp) can be adjusted by the frequency fp.

The burst waveform WF3 such as shown in FIG. 12C is obtained by amplitude-modulating the sine wave WF1 of FIG. 12A with the sawtooth wave WF2 such as shown in FIG. 12B, and therefore includes a frequency 1/Tb determined by the time Tb and the frequency fp of the sine wave WF1, as frequency components. Accordingly, from the findings of Experimental Result 1 of FIG. 9 and Experimental Result 3 of FIG. 11, it is possible to set the frequency fp to be 1 kHz to 10 kHz and the frequency to be 50 Hz to 500 Hz, for example. In this way, when the AC electric field is generated with a plurality of different frequencies, even if nanoparticles having large variations in particle size (smallest particle size of 10 nm and largest particle size of 100 nm, for example) are mixed together in the liquid film Lq on the surface of the sheet substrate P, it is possible to effectively apply the electrophoretic force fz to each of these nanoparticles.

### [Third Modification]

In FIG. 6, with the deposition smoothing section formed by the electrode plates Em and Ef1 to Ef4 and the AC electric field generating section 90, the AC electric field having a certain strength was applied with a certain frequency fp to the liquid film Lq on the surface of the sheet substrate P during the drying process in which the sheet substrate P is moved horizontally in the +X direction. However, since the four electrodes plates Ef1 to Ef4 arranged on the back surface side of the sheet substrate P are divided along the horizontal feeding path of the sheet substrate P, the AC voltage Ev and frequency fp applied to each electrode plate Ef1 to Ef4 may be different. Therefore, it is necessary to provide a plurality of oscillation circuits 90A and adjustment circuits 90B in the AC electric field generating section 90 shown in FIG. 7.

### [Fourth Modification]

The deposition smoothing section shown in FIG. 7, formed by the electrode plates Em and Ef1 to Ef4 and the AC electric field generating section 90, can function as long as the liquid film Lq is formed on the sheet substrate P with a thickness at which electrophoresis of the nanoparticles np is possible (for example, at least several times the particle size of the nanoparticles). Accordingly, the process of forming the liquid film Lq on the substrate P is not limited to the mist deposition method, and the liquid film Lq may be formed by various types of printing (gravure printing, silk printing, die coater printing, or the like) or inkjet coating apparatuses. In particular, in a case of forming a conductive wire pattern, electrode pattern, or the like by selectively applying miniscule droplets containing metal nanoparticles to the surface of a substrate P using the inkjet technique, it is possible to reduce the resistance value of the wire pattern or electrode pattern made of nanoparticles formed on the substrate P by passing the substrate P through a deposition smoothing section such as shown in FIG. 7 before drying the applied droplets.

### [Fifth Modification]

In the second embodiment and the third and fourth modifications, the AC electric field was applied in a direction perpendicular to the surface on which the liquid film Lq expands on the sheet substrate P, that is, between the electrode plate Em and the electrode plates Ef1 to Ef4 shown in FIG. 7. However, by changing the configuration and arrangement of the electrode plates, it is possible to change the orientation of the electrophoretic force fz acting on the nanoparticles in the liquid film Lq to have a vector not only in the vertical direction (Z direction), but also actively in the horizontal direction (within the XY plane).

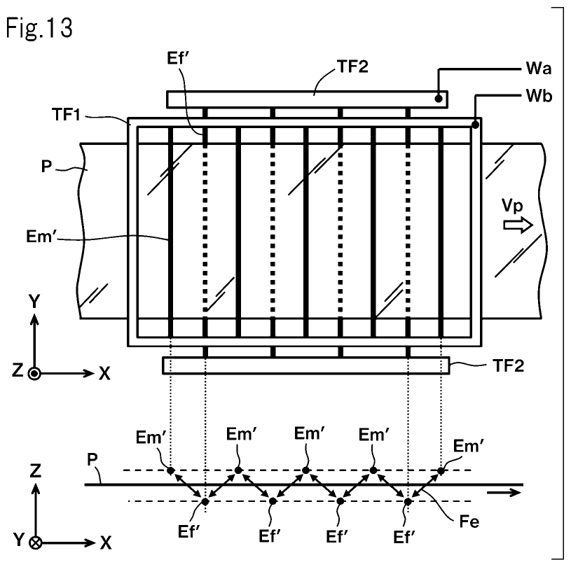

FIG. 13 shows a configuration of a deposition smoothing section (electrophoresis applying section) according to a fifth modification, wherein the top section of FIG. 13 is a top view of the configuration in the XY plan as seen from above and the bottom section of FIG. 13 is a front view of the configuration in the XZ plane as seen from the side. In the fifth embodiment, instead of the electrode board Em arranged on the top surface side of the sheet substrate P, a plurality of electrode lines Em′ (wires or steel lines) extending linearly to be longer in the Y direction than the width (Y-direction dimension) of the sheet substrate P are arranged at constant intervals in the X direction (sheet substrate P transport direction). Both Y-direction ends of each of the plurality of electrode lines Em′ are fixed to a metal frame TF1, and are connected to a wire Wb from the AC electric field generating section 90 shown in FIG. 7 above. Furthermore, in the fifth modification, instead of the electrode plates Ef1 to Ef4 arranged on the back side surface of the sheet substrate P, a plurality of electrode lines (wires or steel lines) Ef′ extending linearly to be longer in the Y direction than the width (Y-direction dimension) of the sheet substrate P are arranged at constant intervals in the X direction (sheet substrate P feeding direction). Both Y-direction ends of each of the plurality of electrode lines Ef′ are fixed to a metal frame TF2, and are connected to a wire Wa from the AC electric field generating section 90 shown in FIG. 7 above.

The plurality of electrode lines Em′ on the top surface side of the sheet substrate P and the plurality of electrode lines Ef′ on the back surface side of the sheet substrate P are arranged in an alternating manner at constant intervals in the X direction, when viewed in the XY plain. When the AC voltage Ev is applied between the frames TF1 and TF2 via the wires Wa and Wb, an AC electrode field Fe that is inclined in the X direction is generated between each electrode line Em′ on the top side and each electrode line Ef′ on the bottom side, as shown in the bottom section of FIG. 13. Therefore, the electrophoretic force fz inclined in the X direction, that is, an electrophoretic force in the Z direction and an electrophoretic force in the X direction, is applied to the nanoparticles in the liquid film Lq on the surface of the sheet substrate P. Due to this, the nanoparticles in the liquid film Lq are actively minutely moved (minutely vibrated) in the horizontal direction as well along the surface of the sheet substrate P, and it becomes possible to increase the smoothing of the deposition state of the thin film made of nanoparticles after drying.

The plurality of electrode lines Em′ and the plurality of electrode lines Ef′ shown in FIG. 13 may all be inclined by a certain angle (45° or 90°, for example) relative to the Y axis (or X axis) in the XY plain, while remaining parallel to each other. Furthermore, when viewed in the XY plane, the plurality of electrode lines Em′ and electrode lines Ef′ do not need to be linear, and may be curved into an arc shape (bow shape) or bent into a zigzag or wavy shape.

According to the second embodiment and third to fifth modifications described above, provided is the deposition apparatus that deposits fine particles (nanoparticles np) on the surface of the sheet substrate P, serving as the processing target substrate, to a prescribed thickness, the deposition apparatus including: the liquid film forming section formed by the mist depositing section, or the coating apparatus using a printing method or inkjet method, for forming the liquid film Lq, made of the solution containing the nanoparticles np, with a prescribed thickness on the surface of the sheet substrate P; and a deposition smoothing section serving as the electrophoresis applying section that, before the liquid film Lq formed on the surface of the sheet substrate P is evaporated or volatilized, applies an AC electric field to the liquid film Lq to apply an electrophoretic force fz to the nanoparticles np in the liquid film Lq. Since the mist deposition apparatus MDE shown in FIG. 6 firmly supports the sheet substrate P with the rotating drum DR having a conductive outer circumferential surface, a first electrode (Em) may be provided on an inner wall surface of the chamber section 40 facing the sheet substrate P, the outer circumferential surface of the rotating drum DR may be a second electrode (Ef), and the AC electric field may be applied between the first electrode (Em) and the second electrode (Ef).

### Third Embodiment

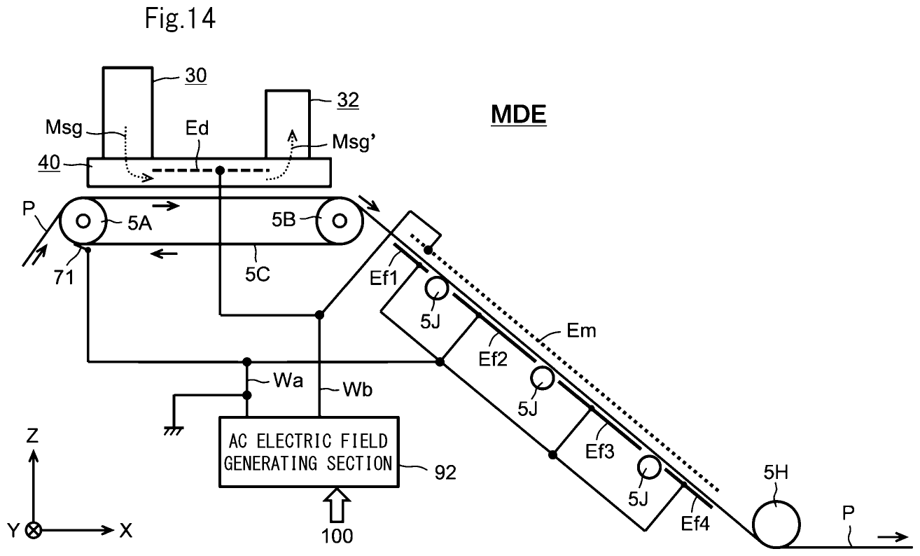

FIG. 14 shows a schematic configuration of a mist deposition apparatus MDE according to a third embodiment, and the orthogonal coordinate system XYZ of FIG. 14 is set in the same manner as the orthogonal coordinate system XYZ of FIGS. 1 and 6 above. The present embodiment is a combination of the mist depositing section shown in FIG. 2 of the first embodiment above and the deposition smoothing section shown in FIG. 7 of the second embodiment. Accordingly, among the components in FIG. 14, components having substantially the same configuration or same function as components in FIG. 1 or 6 above are given the same reference numerals.

In FIG. 14, the sheet substrate P is supported on the horizontal portion of the metal endless belt 5C hung between the rollers 5A and 5B and fed in the −X direction, and the mist gas Msg from the mist depositing section formed by the mist ejecting section 30, the mist recovering section 32, and the chamber section 40 is sprayed onto the surface of the sheet substrate P supported horizontally. The belt 5C is electrically connected to the wire Wa leading from an AC electric field generating section 92 via the contact 71, and the electrode plate Ed, which is arranged above (+Z direction from) the sheet substrate P inside the chamber section 40, is electrically connected to the wire Wb leading from the AC electric field generating section 92. In the present embodiment as well, the mist guidance mechanism is formed by the belt 5C, the electrode plate Ed, and the AC electric field generating section 92.

The sheet substrate P on whose surface the liquid film (Lq) is formed by the mist depositing section exits from the belt 5C at the position of the roller 5B and is fed along the linear feeding path, inclined downward by approximately 45° from the horizontal plane (XY plane), inside the deposition smoothing section. In the same manner as the configuration shown in FIG. 6 above, this feeding path is provided with the plurality of rollers 5J and the plurality of electrode plates Ef1 to Ef4 arranged on the back surface side of the sheet substrate P, as well as the mesh electrode plate Em arranged on the top surface side of the sheet substrate P. The electrode plates Ef1 to Ef4 are electrically connected to the wire Wa leading from the AC electric field generating section 92, and the electrode plate Em is electrically connected to the wire Wb leading from the AC electric field generating section 92. In the present embodiment as well, the deposition smoothing section is formed by the electrode plates Ef1 to Ef4, the electrode plate Em, and the AC electric field generating section 92. The electrode plates Ef1 to Ef4 may be changed to be the plurality of electrode lines Ef′ such as shown in FIG. 13 above, and the electrode plate Em may be changed to be the plurality of electrode lines Em′ such as shown in FIG. 13 above.

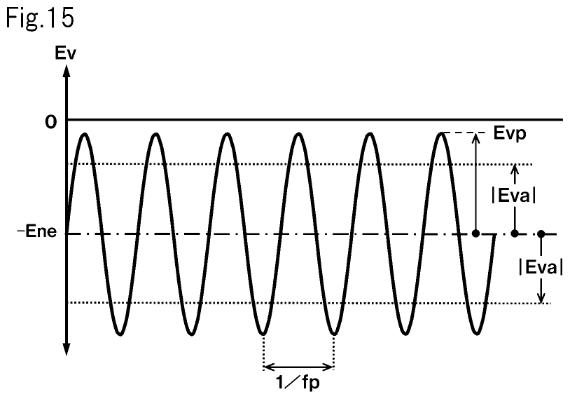

The present embodiment is configured such that the electrostatic field generated by the mist guidance mechanism and the AC electric field generated by the deposition smoothing section are provided from one AC electric field generating section 92. As described in each embodiment and modification above, in the mist guidance mechanism, it is sufficient if the electrode plate Ed is generally negative with respect to the belt 5C, such that the negatively charged mist is guided to the sheet substrate P side. Therefore, the AC electric field generating section 92 is configured to generate an AC voltage Ev such as shown in FIG. 15, for example. In FIG. 15, the vertical axis indicates the AC voltage Ev, the horizontal axis indicates time, and the neutral potential (average potential) of the waveform of the AC voltage Ev whose amplitude changes in strength with the frequency fp in a sinusoidal manner with the effective value Eva is set to be −Ene(V) that is negative relative to the zero potential (ground potential of the main body). The absolute value |Eva| of the effective value Eva of the amplitude and the absolute value |Ene| of the neutral potential −Ene are set to have a relationship of |Ene|≥|Eva|.

When the AC voltage Ev such as shown in FIG. 15 is applied between the belt 5C and the electrode plate Ed in FIG. 14, the magnitude of the force attracting the mist to the sheet substrate P side changes over time with the frequency fp, but since the average strength of the electrostatic field is the neutral potential −Ene, the effect of improving adhesion efficiency of the mist to the sheet substrate P can be obtained to the same degree as in the first embodiment above. On the other hand, when an AC voltage Ev such as shown in FIG. 15 is applied between the electrode plates Ef1 to Ef4 and the electrode plate Em of the deposition smoothing section (electrophoresis applying section) shown in FIG. 14, an AC electric field that is constantly offset to the negative side and whose amplitude changes with the effective value Eva is applied to the liquid film Lq on the sheet substrate P, and therefore the electrophoretic force fz is applied to the nanoparticles in the liquid film Lq in the same manner as in the second embodiment above.

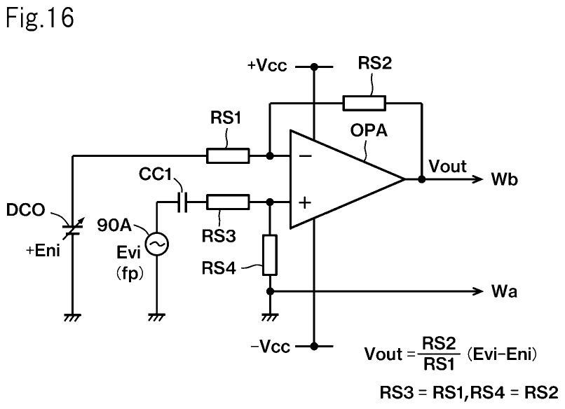

FIG. 16 shows an example of a detailed circuit inside the AC electric field generating section 92 that generates the AC voltage Ev such as shown in FIG. 15, and a differential amplifier OPA capable of operating with a relatively high power source voltage ±Vcc (±50 V or more, for example). A voltage +Eni from a DC variable power source DCO is applied to the inverting input (−) of the differential amplifier OPA via a resistor RS1, and a resistor RS2 is connected between the inverting input (−) and the output of the differential amplifier OPA. A voltage +Eni from the variable power source DCO is for generating the neutral potential (offset voltage) −Ene shown in FIG. 15. A resistor RS4 is connected between the non-inverting input (+) of the differential amplifier OPA and the ground potential (0 V), and the AC voltage Evi with a sinusoidal shape having the frequency fp output from the AC electric field generating section 90A shown in FIG. 7 is applied to the non-inverting input (+) of the differential amplifier OPA, via a serial connection between a coupling capacitor CC1 and the resistor RS3. The capacitance of the capacitor CC1 is determined according to the serial resistance value of the resistors RS3 and RS4, such that the low cutoff frequency of the frequency fp of the AC voltage Evi becomes approximately 1 Hz.

In the circuit configuration of FIG. 16, when the resistor RS1 and resistor RS3 are set to the same resistance value and the resistor RS2 and resistor RS4 are set to the same resistance value, the output voltage Vout relative to the ground potential (connected to the wire Wa) appearing at the output of the differential amplifier OPA is Vout=(RS2/RS1)·(Evi−Eni). The AC voltage Evi is a waveform whose amplitude changes over time in a sinusoidal manner, and therefore, with the peak value being Epi and time being t, the AC voltage Evi can be expressed as Evi=Epi·sin(2π·fp·t). When the absolute value of the peak value Epi of the AC voltage Evi and the absolute value of the voltage +Eni from the variable power source DCO set to a relationship of Epi≤Eni, the output voltage Vout becomes a waveform such as shown in FIG. 15 above. The output voltage Vout of the differential amplifier OPA is applied to the electrode plates Ed and Em shown in FIG. 14, via the wire Wb.

As an example, with the resistors RS1 and RS3 being 20 kΩ and the resistors RS2 and RS4 being 100 kΩ, in a case where the neutral potential (average potential) −Ene of FIG. 15 is set to −25 V and the peak value Evp of the amplitude of the AC voltage Ev in FIG. 15 is set to 22 V, the voltage +Eni caused by the variable power source DCO is set to +5 V and the peak value of the amplitude of the AC voltage Evi from the oscillation circuit 90A is set to 4.4 V (approximately 3.08 V at the effective value). As shown in FIG. 15, the circuit configuration generating the AC voltage Ev whose amplitude changes with the frequency fp with the neutral potential Ene (offset potential) that is not 0 V (ground potential) as a reference is not limited to the circuit configuration shown in FIG. 16, and may be realized by various other circuit configurations.

In the present embodiment, as shown in FIG. 14, in order to feed the sheet substrate P horizontally in the mist depositing section, a conveyor feeding system made up of the rollers 5A and 5B and the belt 5C is used, but instead, as shown in FIG. 6 above, a roller feeding system in which the sheet substrate P is wound around the rotating drum DR in the mist depositing section may be used.

According to the third embodiment described above, the electrostatic field generating section, which generates the electrostatic field between the belt 5C and the electrode plate Ed serving as the mist guidance mechanism provided in the mist depositing section, can be used as the AC electric field generating section, which generates the AC electric field between the electrode plate Em and the electrode plates Ef1 to Ef4 serving as the deposition smoothing section (electrophoresis applying section) attempting to smooth the deposition distribution of nanoparticles in the liquid film on the substrate during the drying process immediately after the mist deposition, thereby making it possible to simplify the configuration of the apparatus. Furthermore, when applying the AC electric field to the liquid film Lq on the sheet substrate P with the deposition smoothing section (electrophoresis applying section), the neutral potential (Ene) and the amplitude range of the AC electric field are offset toward the same polarity side (negative polarity side), and therefore the polarized nanoparticles np in the liquid film Lq are provided with both an electrophoretic force (vibration) and an inductive force attracting the nanoparticles np toward the sheet substrate P side.

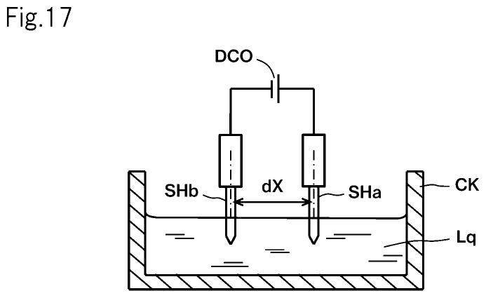

When an experiment was performed that involved immersing two electrode needles at a prescribed interval from each other in a solution Lq (liquid film Lq) in which ITO nanoparticles, crystallized into rectangular parallelepiped shapes according to the manufacturing method disclosed in WO 2019/138707 A1 and WO 2019/138708 A1, are dispersed and applying a DC voltage between the electrode needles for a certain time, a thin film was formed by deposition of the ITO nanoparticles on the surface of one of the electrode needles. FIG. 17 shows a schematic configuration of this experimentation apparatus, wherein a solution Lq (solvent or pure water), in which ITO nanoparticles crystallized into rectangular parallelepiped shapes are dispersed, was stored to a certain depth in a container CK such as a petri dish, two gold-plated electrode needles SHa and SHb distanced from each other by an interval dX in a direction parallel to the liquid surface were each immersed perpendicular to the liquid surface, and 40 V was applied from the DC variable power source DCO between the electrode needles SHa and SHb.

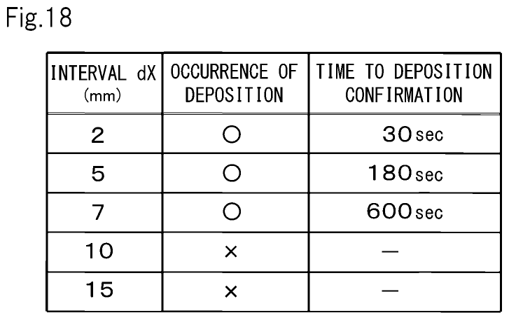

In this experiment, in a state where the voltage of the DC variable power source DCO was set to 40 V, the interval dX between the two electrode needles SHa and SHb was changed and a visual check was made concerning whether the ITO nanoparticles formed a film (were deposited) on one of the electrode needles. Since the surfaces of the electrode needles SHa and SHb are gold-plated, when deposition of the ITO nanoparticles begins, the immersed portion of the electrode needle SHb begins turning gray, and therefore can easily be seen by eye. As shown in FIG. 18, the result of the experiment was that deposition could not be confirmed for intervals dX of 10 mm or more, but in the state where the electrodes where immersed directly in the solution Lq with intervals dX of 2 mm, 5 mm, and 7 mm, ITO nanoparticles with rectangular parallelepiped shapes formed film (were deposited) on one of the electrode needles, and therefore it is believed that a kinetic force (repulsive force or attractive force) was applied to the ITO nanoparticles in the region (space) where the electric field acted between the electrode needles SHa and SHb.

### Fourth Embodiment

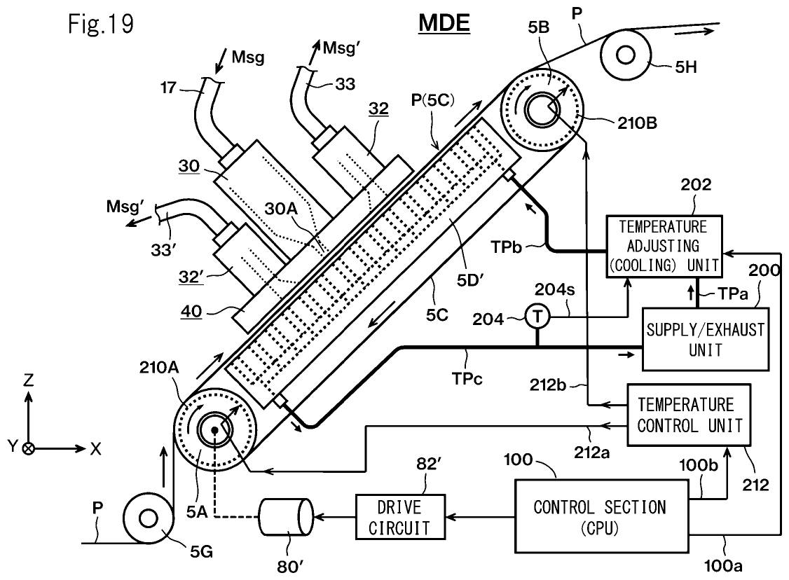

FIG. 19 is a schematic view showing a schematic configuration of the mist deposition apparatus MDE according to a fourth embodiment, and the orthogonal coordinate system XYZ is set such that the Z direction is the direction of gravity and the XY plane is in the horizontal direction, in the same manner as in FIGS. 1, 4, 6, and 14 above. The mist depositing section according to the present embodiment is configured to form the liquid film Lq by spraying the mist gas Msg onto the surface of the sheet substrate P while moving the sheet substrate P in the length direction with the conveyor feeding system shown in FIGS. 1 to 3B or 14 above. Accordingly, in the configuration of the apparatus shown in FIG. 19, components and mechanisms having the same function as components and mechanisms shown in FIGS. 1 to 3B or FIG. 6 above are given the same reference numerals, and descriptions thereof are omitted or simplified.

In the present embodiment, in the conveyor feeding mechanism made up of the rollers 5A and 5B and the belt 5C, the portion of the belt 5C supporting the sheet substrate P in a flat state moves linearly from the roller 5A toward the roller 5B, and is arranged in a manner to be inclined by a certain angle from the XY plane in the movement direction of the sheet substrate P. In other words, the roller 5B positioned on the downstream side in the sheet substrate P feeding direction is arranged higher than the position of the roller 5A in the Z direction. Due to the surface of the sheet substrate P being inclined in the feeding direction in this manner, the entire mist depositing section formed by the mist ejecting section 30, the mist recovering section 32 or 32′, and the chamber section 40 is also arranged at an incline. Furthermore, in the same manner as in FIG. 1 above, a support table 5D′ that supports the belt 5C and the sheet substrate P in a flat state is provided inclined in the feeding direction relative to the XY plane, between the roller 5A and the roller 5B. A plurality of sets of an ejection hole, which ejects pressurized gas toward the back surface of the belt 5C, and a suction hole, which sucks in the ejected gas near the ejection hole, are provided two-dimensionally at constant intervals in the support surface of the support table 5D′, to form an air bearing layer (gas layer) between the back surface of the belt 5C and the support surface.

In the present embodiment, in order to cause the air bearing layer formed between the support surface of the support table 5D′ and the back surface of the belt 5C to be a lower temperature than the temperature of the mist gas Msg ejected from the nozzle opening 30A of the mist ejecting section 30 (or the ambient temperature), a supply/exhaust unit 200, a temperature adjusting (cooling) unit (temperature adjusting section) 202, and a temperature sensor 204 are provided. The supply/exhaust unit 200 discharges the gas of the air bearing layer via a tube TPc in communication with all of the plurality of suction holes formed in the support surface of the support table 5D′, and supplies pressurized gas toward the temperature adjusting (cooling) unit 202 via a tube TPa. The temperature adjusting (cooling) unit 202 supplies temperature-adjusted gas for the air bearing layer, through a tube TPb in communication with all of the plurality of ejection holes formed in the surface of the support table 5D′. The temperature sensor 204 outputs measurement information (measured value) 204s corresponding to the temperature of the gas recovered from the air bearing layer and flowing through the tube TPc, to the temperature adjusting (cooling) unit 202. The temperature adjusting (cooling) unit 202 performs servo control of the gas temperature such that the measurement information (measured value) 204s matches target temperature information (instruction value) 100a from the control section (CPU) 100.

The control section 100 is the same as in FIG. 6 above and, in the present embodiment, outputs a control signal to the drive circuit section 82′ of the drive section 80′ including the motor or decelerator that rotationally drives the roller 5A to feed the belt 5C. Furthermore, in the present embodiment, a temperature control unit 212 is provided that drives a temperature adjusting element (Peltier element, for example) 210A provided inside the roller 5A and a temperature adjusting element (Peltier element, for example) 210B provided inside the roller 5B, in a manner to be set to a prescribed temperature corresponding to a target temperature information 100b from the control section 100. The temperature adjusting elements (temperature adjusting section) 210A and 210B cause the temperatures of the outer circumferential surfaces of the respective rollers 5A and 5B contacting the belt 5C to be the same as the temperature of the air bearing layer formed on the support surface of the support table 5D′. By having such temperature adjusting elements 210A and 210B work together with the temperature adjusting (cooling) unit 202, the belt 5C is set to the target temperature as instructed by the control section 100, and the sheet substrate P firmly supported by the belt 5C is also set to the target temperature.

In a case where the belt 5C is a metal thin plate of stainless steel or the like, the rate of heat transfer is high, and therefore the temperature adjusting element 210B in the roller 5B (downstream side in the feeding direction of the sheet substrate P) may be omitted and the temperature adjustment of the belt 5C may be performed by only the temperature adjusting element 210A on the roller 5A side, and furthermore, the temperature adjusting element 210A and the temperature control unit 212 may also be omitted. Furthermore, the temperature sensor 204 measures the temperature of the gas passing through the tube TPc, but may be a temperature sensor made of a conductive body or the like that is embedded in support surface of the support table 5D′, measures the temperature of the support surface or the temperature of the gas of the air bearing layer, and sends a measurement signal to the temperature adjusting (cooling) unit 202 as the measurement information (measured value) 204s.

In the present embodiment, in order to efficiently adhere the mist in the mist gas Msg ejected from the nozzle opening 30A of the mist ejecting section 30 to the surface of the sheet substrate P, the target temperature information 100a and 100b from the control section 100 is set such that the temperature of the sheet substrate P becomes lower than the temperature of the mist gas Msg (or the ambient temperature). Here, with the temperature of the environment in which the mist deposition apparatus MDE of FIG. 19 is installed being Tev° C., the temperature of the mist gas Msg sprayed from the nozzle opening 30A of the mist ejecting section 30 being Tms° C., and the temperature of the sheet substrate P (deposition target object) being Tfs° C., it is preferable to set a relationship of Tev Tms>Tfs. At this time, temperature adjustment is performed by the temperature adjusting (cooling) unit 202 and the temperature control unit 212 such that the temperature Tfs of the sheet substrate P becomes a temperature approximately equal to or slightly higher than the freezing point temperature of the solvent liquid of the solution Lq serving as the source of the mist.

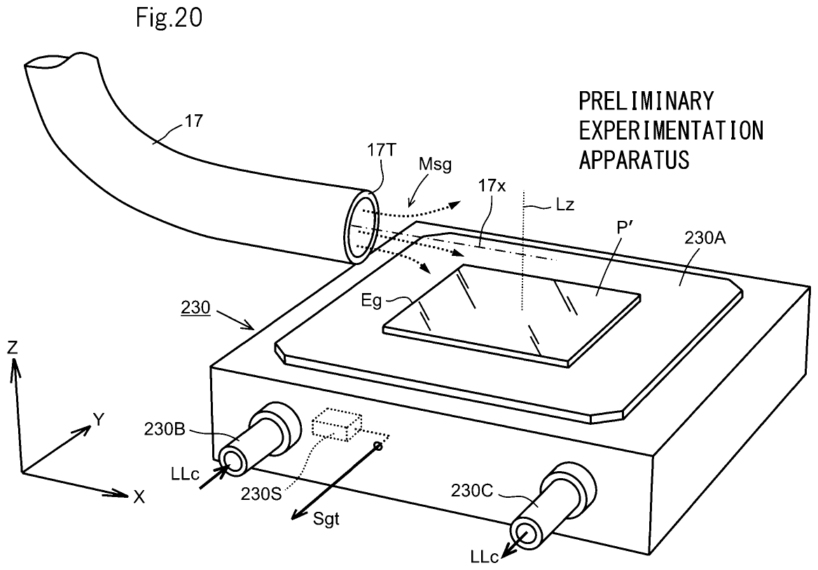

In order to check the optimal value or the like for the temperature of the cooled sheet substrate P, the temperature dependency of the mist adhesion efficiency was investigated using a preliminary experimentation apparatus such as shown in FIG. 20. In the preliminary experimentation apparatus of FIG. 20, a glass substrate P′ is placed as a sample, a temperature adjusting unit (substrate temperature adjusting section) 230 is provided that can cool the glass substrate P′ from room temperature (ambient temperature) to −5° C., and a pipe 17 is provided from a mist generator arranged such that the mist gas Msg is sprayed along the surface of the glass substrate P′. The pipe 17 is the same as the flexible pipe 17 (PTFE: fluororesin) connected to the mist ejecting section 30 from the mist generating section 14 shown in FIG. 1 above, for example. The pipe 17 is arranged such that a center line 17x (line passing through the center point of the circular opening of a tip opening 17T) of the speaking of the mist gas Msg ejected from the tip opening (ejection port) 17T that is circular with an inner diameter (diameter) φ of 15 mm is approximately parallel to the surface of the glass substrate P′. It should be noted that the glass substrate P′ was cut out from a glass plate (which may be a semiconductor wafer) having a thickness of 0.5 mm and whose surface was treated to be lyophilic, to be a square of approximately 25 mm on each side.

Here, the center line 17x is set to be parallel to the X axis of the orthogonal coordinate system XYZ in which the Z direction is the direction of gravity. Accordingly, the surface of the glass substrate P′ is set to be parallel to the XY plane, a normal line Lz passing through the center point of the surface of the glass substrate P′ is set parallel to the Z axis, and the open plane of the tip opening 17T of the pipe 17 is set to be parallel to the YZ plane. Furthermore, the glass substrate P′ (with a square shape) is loaded on the temperature adjusting unit 230 such that the end surface Eg on the pipe 17 side is approximately parallel to the Y axis and the distance in the X direction from the tip opening 17T of the pipe 17 to the end surface Eg is approximately constant (10 mm, for example). Furthermore, the tip opening 17T of the pipe 17 is fixed by a support member (not shown in the drawings) such that the Z-direction interval between the surface of the glass substrate P′ and the center line 17x is a constant value in a range of 0.5 times to 1.5 times the inner diameter φ, for example.

The temperature adjusting unit (substrate temperature adjusting section) 230 includes a temperature adjusting plate 230A on which the glass substrate P′ is placed, a supply port portion 230B into which a temperature adjustment liquid (coolant liquid) LLc for adjusting the temperature of the temperature adjusting plate 230A flows, an exhaust port portion 230C that discharges the temperature adjusting liquid LLc, and a temperature sensor 230S. The temperature adjusting liquid LLc is sent to the supply port portion 230B from a chiller apparatus (cooled water or hot water circulation device) provided separately, via a tube, and returned to the chiller apparatus from the exhaust port portion 230C via the tube. The temperature sensor 230S transmits a detection signal Sgt corresponding to the temperature of the temperature adjustment liquid LLc to the chiller apparatus, and the chiller apparatus uses the detection signal Sgt as a feedback signal to perform temperature control such that the temperature adjustment liquid LLc becomes the target temperature as instructed. The temperature sensor 230S that measures the temperature of the temperature adjustment liquid LLc may be provided on the chiller apparatus side.

In the experiment using the experimentation apparatus of FIG. 20, the target temperature of the chiller apparatus was set such that the temperature of the glass substrate P′ was changed to each of a room temperature of +27° C. (ambient temperature) followed by temperatures from +25° C. to −5° C. at intervals of 5° C. Furthermore, in order to check for effects caused by the temperature of the mist gas Msg sprayed from the pipe 17 in addition to the temperature change of the glass substrate P′, the experiment was performed for cases where the mist gas Msg was changed to +10° C., +30° C., and +50° C. For the experiment performed using the experimentation apparatus of FIG. 20, ITO nanoparticles (average particle size of 30 nm) having rectangular parallelepiped shapes created according to the manufacturing method disclosed in WO 2019/138707 A1 and WO 2019/138708 A1 were dispersed with a concentration of 10 wt. % in the solution (pure water) Lq stored inside the inner container 14A of the mist generating section (mister) 14 shown in FIG. 1 above.

Furthermore, the time (deposition time) during which the mist gas Msg is sprayed was set to five minutes (300 sec) per glass substrate P′ serving as a sample, and the flow rate of the mist gas Msg ejected from the tip opening 17T of the pipe 17 was set to be a constant value (10 L/min) for each glass substrate P′, using the carrier gas CGS flow rate adjusting valve 15 shown in FIG. 1. Furthermore, the temperature of the mist gas Msg can be easily changed by adjusting the temperature of the carrier gas CGS guided by the mist generating section 14 shown in FIG. 1. However, in order to perform more rigorous experimentation, before the glass substrate P′ was placed at the prescribed position on the temperature adjusting plate 230A, a rod-shaped thermometer with an alcohol column or a mercury column was held over the mist gas Msg ejected near the tip opening 17T to directly measure the temperature, and the temperature of the carrier gas CGS was managed to be the prescribed temperature (+10° C., +30° C., or +50° C.).

In this experiment, first, the temperature of the mist gas Msg was set to +10° C., the mist gas Msg was sprayed for five minutes (mist deposition) from the tip opening 17T of the pipe 17 in a state where the temperature of the temperature adjusting plate 230A (and the glass substrate P′ placed thereon) was set to the room temperature of +27° C., and then the glass substrate P′ was taken off the temperature adjusting plate 230A and dried. In order to investigate the thickness of the thin film made of ITO nanoparticles with rectangular parallelepiped shapes formed on the dried glass substrate P′, the step amount (in other words, the film thickness) between the top surface of the thin film and the surface of the glass substrate P′ revealed by locally scraping away the thin film of the central portion of the glass substrate P′ was measured by a needle-type film thickness measuring instrument (for example, the Surface Profiler P16 manufactured by KLA-Tencor).

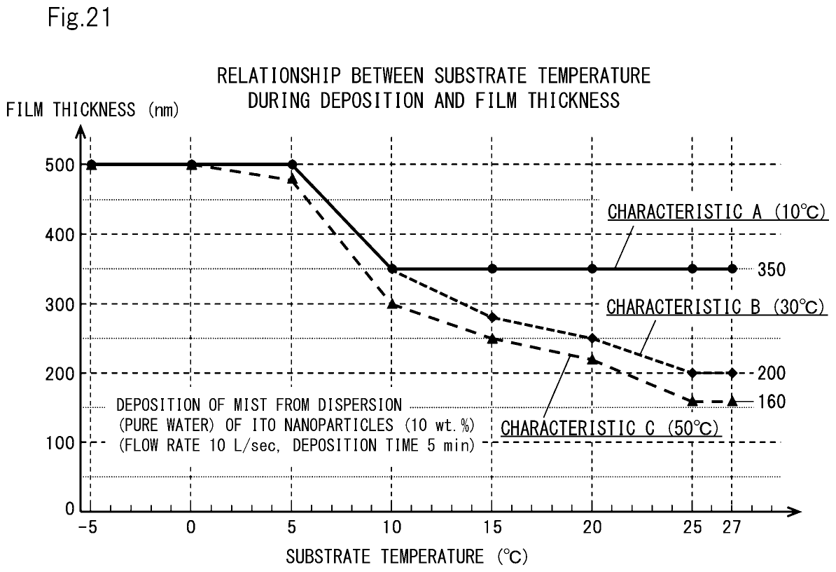

In the same manner, the temperature of the temperature adjusting plate 230A (and the glass substrate P′ placed thereon) was changed to each of +25° C., +20° C., +15° C., +10° C., +5° C., 0° C., and −5° C., the mist gas Msg at +10° C. was deposited on the surface of the glass substrate P′, and the thickness of the thin film made of ITO nanoparticles after drying was investigated. As a result, when the temperature of the mist gas Msg was +10° C., the relationship between the film thickness of the thin film made of deposited ITO nanoparticles and the temperature of the substrate was as shown by the characteristic A in the graph of FIG. 21. FIG. 21 is a graph representing the dependency, on the substrate temperature, of the film thickness of the deposited thin film, with the horizontal axis indicating the substrate temperature (° C.) and the vertical axis indicating the film thickness (nm) of the thin film (ITO nanoparticles).

In the case where the temperature of the mist gas Msg was +10° C., the film thickness of the deposited thin film when the substrate temperature was from the room temperature of +27° C. to +10° C. was approximately 350 nm and did not change, as shown by the characteristic A. However, when the substrate temperature became less than +10° C. (less than or equal to the temperature of the mist gas Msg), that is, at the temperatures of +5° C., 0° C., and −5° C., the film thickness of the deposited thin film increased by approximately 1.43 times to about 500 nm. This means that a greater amount of the mist contained in the mist gas Msg during mist deposition was attracted to the glass substrate P′ side when the glass substrate P′ was at a lower temperature than the mist, that is, the adhesion of the mist on the substrate surface was improved. From this, it becomes possible to improve the mist adhesion efficiency and more quickly grow the liquid film layer formed by the aggregation of innumerable mist particles (particle size of several micrometers) on the surface of the deposition target, by causing the temperature of the sheet substrate P serving as the deposition target to be lower than the temperature of the mist gas Msg.

In the case where the substrate temperature was −5° C., the mist (pure water) that adhered to the surface of the glass substrate P′ immediately froze, and therefore a layer of thin frost (ice layer) was formed on the surface of the glass substrate P′ after the mist spraying time (five minutes). In this case as well, as time passes after the mist spraying, the ice layer changes to a layer of liquid film and ultimately this liquid film also evaporates (or becomes a gas), and therefore it is possible to measure the thickness of the thin film resulting from the deposition of ITO nanoparticles in the same manner.

Next, the temperature of the carrier gas CGS was adjusted, the temperature of the mist gas Msg was increased to +30° C., and the experiment was performed in the same manner as in the case of +10° C., with the result being that the relationship between the substrate temperature and the thickness of the ITO nanoparticle thin film was as shown by the characteristic B in the graph of FIG. 21. When the temperature of the glass substrate P′ was the room temperature of +27° C. (or +25° C.), the film thickness was approximately 200 nm for a mist gas Msg temperature of +30° C., which was a lower deposition amount (deposition rate) than the film thickness (approximately 350 nm) realized when the temperature of the mist gas Msg was +10° C. Furthermore, the temperature of the glass substrate P′ was set to each of +20° C., +15° C., +10° C., +5° C., and 0° C. and the thickness of the thin film made of deposited ITO nanoparticles was measured, whereupon, as shown by the characteristic B, in the substrate temperature region of +10° C. or less, the change in the amount of film thickness relative to the substrate temperature exhibited the same trend as in the case where the mist gas Msg temperature was +10° C. and a film thickness of approximately 500 nm was obtained for a substrate temperature of +5° C. or more.

Furthermore, the temperature of the carrier gas CGS was adjusted, the temperature of the mist gas Msg was increased to +50° C., and the experiment was performed in the same manner as in the case of +10° C. and +30° C., with the result being that the relationship between the substrate temperature and the thickness of the ITO nanoparticle thin film was as shown by the characteristic C in the graph of FIG. 21. When the temperature of the glass substrate P′ was room temperature of +27° C. (or +25° C.), the film thickness was approximately 160 nm for a mist gas Msg temperature of +50° C., which was less than half the deposition amount (deposition rate) compared to the film thickness (approximately 350 nm) realized when the temperature of the mist gas Msg was +10° C. After this, the temperature of the glass substrate P′ was set to each of +20° C., +15° C., +10° C., +5° C., and 0° C. and the thickness of the thin film made of deposited ITO nanoparticles was measured. The film thickness in the case where the substrate temperature was +10° C. was approximately 300 nm, which is approximately two times the film thickness of 160 nm realized when the substrate temperature was room temperature (+27° C.) or +25° C. Furthermore, the film thickness in the case where the substrate temperature was +5° C. was approximately 480 nm, which is approximately three times the film thickness of 160 nm realized when the substrate temperature was room temperature (+27° C.) or +25° C.

From the result of the preliminary experiment described above, it was determined that by lowering the substrate temperature relative to the temperature of the mist gas Msg, the adhesion efficiency of the mist (growth rate of the liquid film) is improved, and the deposition rate of the nanoparticle deposition is improved. Furthermore, it was determined that in a case where the solution serving as the source of the mist is pure water, when the substrate temperature is set in a range from +10° C. to 0° C., more preferably a range from +5° C. to 0° C., it is possible to realize the greatest increase in the mist adhesion efficiency, regardless of the temperature of the mist gas Msg.

With the experimentation apparatus of FIG. 20, the mist gas Msg is ejected into a free space at the room temperature of +27° C. along the surface of the glass substrate P′ in the horizontal direction from the tip opening 17T of the pipe 17. In such a case, when the temperature of the mist gas Msg is higher than the room temperature of +27° C., the mist gas Msg ejected from the tip opening 17T of the pipe 17 experiences a rising force (floating force) oriented upward (+Z direction), and in a case where the glass substrate P′ is set to the same temperature as the ambient temperature, the amount of mist adhering (falling) to the surface thereof is reduced. However, it is thought that when the temperature of the glass substrate P′ becomes sufficiently lower than the temperature of the mist gas Msg, the temperature of a portion of the mist gas Msg traversing the surface of the glass substrate P′ becomes lower than the surrounding temperature (room temperature) and this portion of the mist gas Msg experiences a falling force (settling force), which improves the mist adhesion force.

Here, in the mist deposition apparatus MDE shown in FIG. 19, with the temperature of the mist gas Msg ejected from the nozzle opening 30A of the mist ejecting section 30 toward the substrate P inside the chamber section 40 being Tms (° C.); the temperature of the surface of the substrate P that has been temperature-adjusted via the belt 5C and the support table 5D′, which are temperature-adjusted by the temperature adjusting (cooling) unit 202, being Tpp (° C.); and the temperature inside the chamber section 40 (the temperature of the space inside the chamber section 40 or the temperature of the inner wall surfaces defining the space inside the chamber section 40) being Tct (° C.), the temperature Tpp may be set to be greater than or equal to the freezing point temperature of the solution serving as the mist source, and a relationship of Tpp<Tms≤Tct may be established. When the mist gas Msg continues to be sprayed for a long time inside the chamber section 40, the temperature Tct of the inside of the chamber section 40 (inner wall surfaces) becomes the same as the temperature Tms of the mist gas Msg.

Therefore, with the mist deposition apparatus MDE shown in FIG. 19, the temperature (Tpp) of the sheet substrate P whose temperature is adjusted by the temperature adjusting (cooling) unit 202 and the temperature control unit 212 is set from 0° C. to +5° C., for example, and the temperature (Tms) of the mist gas Msg ejected from the nozzle opening 30A of the mist ejecting section 30 is set to a temperature that is near the temperature of the sheet substrate P and lower than room temperature (ambient temperature), such as +5° C. to +10° C., for example. The temperature (Tms) of the mist gas Msg may be the same as the set temperature (Tpp) of the substrate P, within a range that does not cause the mist to freeze. In this way, by lowering the temperature (Tpp) of the sheet substrate P within a range where the mist does not freeze, the mist adhesion efficiency is improved and the liquid film deposited on the surface of the substrate P grows more quickly, and therefore it is possible to improve the deposition rate of the thin film made of the nanoparticles contained in the mist. The improvement in the deposition rate leads to the effects of improving the feeding velocity of the sheet substrate P and reducing the flow rate (flow velocity) of the mist gas Msg from the mist ejecting section 30 (reducing the amount of the solution Lq consumed by the mist generating section 14), and so it is possible to more efficiently use the nanoparticles of the deposited material.

### Fifth Embodiment

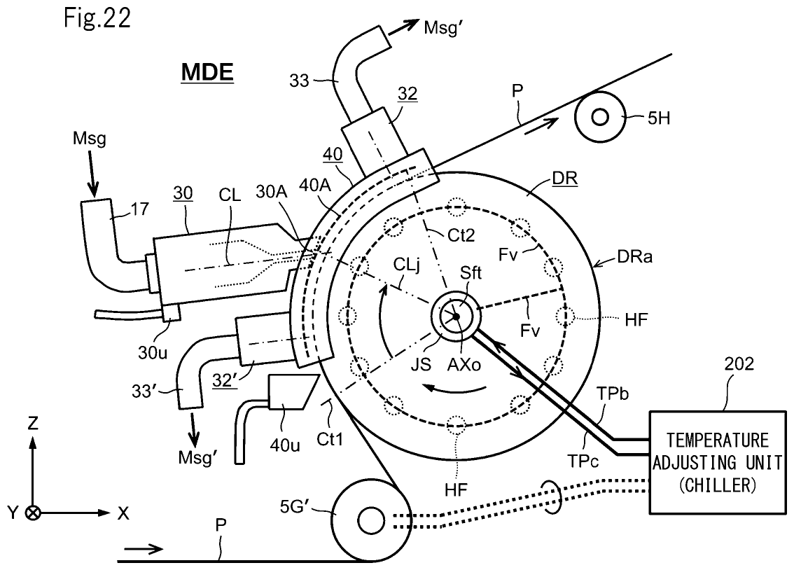

The configuration that lowers the temperature of the sheet substrate P such as shown in FIG. 19 can also be applied to the mist deposition apparatus that supports the sheet substrate P with the rotating drum DR and feeds the sheet substrate P in the length direction, such as shown in FIGS. 4 to 6 above. FIG. 22 shows a configuration of the mist deposition apparatus MDE according to a fifth embodiment that uses the rotating drum DR, and the basic configuration and basic components are the same as the configuration and components shown in FIGS. 4 to 6, and components having the same functions are given the same reference numerals. Furthermore, the orthogonal coordinate system XYZ is set in the same manner as in FIG. 4. In the present embodiment, in order to cool the outer circumferential surface DRa of the rotating drum DR supporting the sheet substrate P, a plurality (12 in FIG. 22) of pipe-shaped cooling pipes (heat exchange pipes), through which is passed a temperature adjustment fluid (temperature-controlled gas or fluid) supplied from the temperature adjusting (cooling) unit 202 via a tube TPb, are provided inside the rotating drum DR. In the case of FIG. 22, each of the plurality of cooling pipes HF is arranged at a position that is a constant radius from the center line AXo of the rotation of the rotating drum DR, and the cooling pipes HF extend parallel to the center line AXo and are arranged at constant angular intervals (30 degrees in the present modification) in the circumferential direction of the outer circumferential surface DRa of the rotating drum DR.

The temperature adjustment fluid supplied via the tube TPb is supplied in a manner to circulate through each of the 12 cooling pipes HF, via a port JS provided in the shaft Sft portion of the rotating drum DR and a flow path Fv provided inside the rotating drum DR. The temperature adjustment fluid circulating through the cooling pipes HF is returned to the temperature adjusting unit 202 via the internal flow path Fv, port JS, and tube TPc, and is controlled to again be the prescribed temperature and sent through the tube TPb. In the present embodiment, in order to perform preliminary temperature adjustment (cooling) of the sheet substrate P before proceeding onto the rotating drum DR, a configuration is provided that sets the outer circumferential surface of the roller 5G′ arranged on the upstream side of the rotating drum DR to a temperature lower than the ambient temperature, using the temperature adjustment fluid from the temperature adjusting unit 202.

As described in relation to the apparatus configuration of FIG. 4 above, the sheet substrate P contacts the outer circumferential surface DRa in a range from the entry position Ct1 to the exit position Ct2 in the circumferential direction of the rotating drum DR, and the chamber section 40 forming the mist depositing section is arranged in a manner to curve in a cylindrical shape in the circumferential direction in an angle range from the entry position Ct1 to the exit position CT2 to cover the sheet substrate P. The mist ejecting section 30 and the mist recovering sections 32 and 32′ are provided in the chamber section 40 with the same arrangement as in FIG. 6 above, but in the present embodiment, the mist ejecting section 30 is provided at an incline such that the line CL indicating the ejection direction of the mist gas Msg ejected from the nozzle opening 30A of the mist ejecting section 30 is not parallel to a line normal to the tangent plane at a position (position through which the line CLj extended in the radial direction from the center line AXo in FIG. 22 passes) on the surface of the sheet substrate P facing the nozzle opening 30A.

In the case of the present embodiment, the mist ejecting section 30 is arranged at an incline such that the nozzle opening 30A side of the mist ejecting section 30 is positioned farther in the +Z direction than the pipe 17 side, that is, such that the +X-direction side of the line CL is higher than the −X-direction side of the line CL, when viewed in the XZ plane. With such a configuration, even in a case where a portion of the mist in the mist gas Msg gathers and becomes a droplet adhered to the inner wall surface of the mist ejecting section 30, the possibility of this droplet becoming large and falling along the inner wall surface and onto the sheet substrate P from the nozzle opening 30A can be made extremely small. Furthermore, as shown in FIG. 22, since a droplet adhered to the inner wall surface of the mist ejecting section 30 flows down in the −Z direction that is the direction of gravity, it is possible to provide a droplet trap section (collecting section) 30u in a portion positioned farthest downward in the inner wall surface.

Furthermore, when the inner wall surface of the air guide member 40A of the chamber section 40 is made to be suitably lyophilic, the mist enters a liquid film state covering the inner wall surface of the air guide member 40A before aggregating locally to form a droplet (grain), and this liquid film eventually flows downward (−Z direction) along the inner wall surface. Therefore, in the present embodiment, a collecting section 40u for the liquid film flowing down along the inner wall surface of the air guide member 40A is provided near the end portion of the chamber section 40 positioned farthest downward in the direction of gravity.

In a case where the outer circumferential surface DRa of the rotating drum DR is at a temperature lower than room temperature (ambient temperature), such as shown in FIG. 22, the sheet substrate P contacts (firmly contacts) the low-temperature outer circumferential surface DRa for the first time at the entry position Ct1, and is cooled while moving from the entry position Ct1 to the exit position Ct2. In the case of the present embodiment, the mist deposition (adhesion of the mist to the substrate surface) is mostly performed in the area from the position of the nozzle opening 30A of the mist ejecting section 30 (position of the line CLj) to the position of the mist recovering section 32 on the downstream side (near the exit position Ct2). Accordingly, it is necessary to keep the sheet substrate P at the target temperature while the sheet substrate P is moving from the position of the line CLj to the exit position Ct2.

As an example, in a case where the temperature of the outer circumferential surface DRa of the rotating drum DR is set in a range from 0° C. to +5° C. with the temperature of the sheet substrate P on the upstream side of the entry position Ct1 being room temperature (+20° C. to +25° C., for example), when the thermal conductivity of the substrate P is low, there is a possibility that the temperature of the surface of the substrate P will not decrease to the temperature of the outer circumferential surface DRa of the rotating drum DR within the time during which the sheet substrate P moves from the entry position Ct1 to the position of the line CLj (position directly below the nozzle opening 30A). Therefore, in the present embodiment, the surface of the roller 5G′ arranged on the upstream side of the rotating drum DR is cooled to a temperature of 10° C. or less (possibly to around 0° C.), for example, by the temperature adjustment fluid (coolant) from the temperature adjusting unit 202. Although the sheet substrate P is preliminarily cooled during the time while in contact (firm contact) with the roller 5G′, with the diameter of the outer circumferential surface of the roller 5G′ being φd (mm), the holding angle (angle range of contact) of the sheet substrate P on the roller 5G′ being Δθr (degrees), and the feeding velocity of the sheet substrate P being Vp (mm/sec), the time Tph (sec) described above is determined as Tph=(π·φd·Δθr)/(360·Vp).

The sheet substrate P that has been preliminarily cooled by the roller 5G′ is cooled to a temperature near the temperature of the outer circumferential surface DRa of the rotating drum DR (0° C. to +5° C.) at the point in time when the sheet substrate P reaches the entry position Ct1 at the outer circumferential surface DRa of the rotating drum DR, and after this, the mist deposition (mist spraying) is performed in a state where the sheet substrate P has reached the target temperature of the outer circumferential surface DRa, while moving from the entry position Ct1 to the position of the line CLj (position directly below the nozzle opening 30A).

In the embodiment described above, the ejection direction (line CL) of the mist gas Msg from the nozzle opening 30A of the mist ejecting section 30 is inclined toward the downstream side in the feeding direction of the sheet substrate P, and therefore the flow rate of the mist gas Msg flowing inside the space from the nozzle opening 30A to the mist recovering section 32 on the downstream side, which is a portion of the space inside the chamber section 40 (space between the air guide member 40A and the substrate P), can be made greater than the flow rate of the mist gas Msg flowing inside the space from the nozzle opening 30A to the mist recovering section 32′ on the upstream side. The configuration in which the ejection direction of the mist gas Msg from the nozzle opening 30A of the mist ejecting section 30 is inclined from the direction perpendicular to the sheet substrate P in this way can also be applied in the same manner to the mist deposition apparatuses shown in each of FIGS. 1 to 3B, 4, 6, 14, and 19 above.

In the mist deposition apparatus MDE shown in FIGS. 19 and 22, in a case where the temperature of the mist gas Msg ejected from the nozzle opening 30A of the mist ejecting section 30 is set to be a first temperature in a range from 0° C. to 15° C., the temperature of the sheet substrate P cooled by the substrate temperature adjusting mechanism due to the temperature adjusting (cooling) unit 202 in FIG. 19 or the temperature adjusting unit (chiller) 202 in FIG. 22 is set to a second temperature that is in a range from 0° C. to 15° C. and lower than the first temperature. However, in a case where the solvent of the solution Lq serving as the source of the mist is pure water, there is a possibility of the adhered mist freezing into frost when the temperature of the sheet substrate P is set to 0° C., and therefore the temperature of the sheet substrate P is actually set to a temperature higher than 0° C. (+4° C. or more, for example).

### Sixth Embodiment

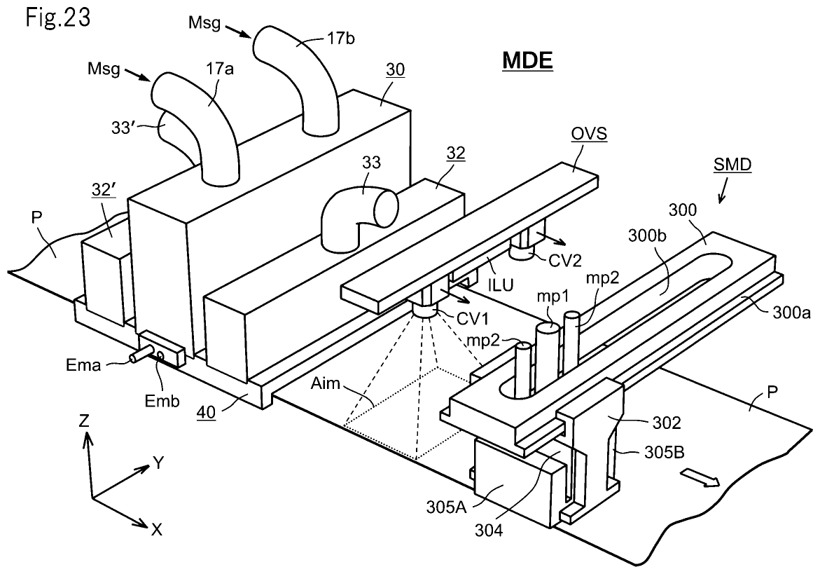

FIG. 23 is a perspective view of a schematic configuration of the mist deposition apparatus MDE according to a modification of the mist deposition apparatus shown in FIG. 19 above (fourth embodiment). In FIG. 23, the Z axis of the orthogonal coordinate system XYZ is the direction of gravity, and the XY plane orthogonal to the Z axis is set to be parallel to the surface of the sheet substrate P on which mist deposition is performed. However, in the same manner as in the embodiment of FIG. 19, the sheet substrate P may be inclined in the length direction (X direction) relative to the XY plane in this modification as well. In FIG. 23 as well, components that are the same as the rollers 5A and 5B, the belt 5C, and the support table 5D′ described in FIG. 19 are provided below (−Z direction from) the sheet substrate P, and the sheet substrate P is cooled.

In FIG. 23, the chamber section 40 is installed in a manner to cover the surface of the sheet substrate P on the upstream side in the feeding direction (+X direction) of the sheet substrate P being fed in a flat state, and the chamber section 40 is provided with the mist ejecting section 30, which is supplied with the mist gas Msg via the two pipes 17a and 17b, and the mist recovering sections 32 and 32′, which recover the surplus portion of the mist gas Msg ejected inside the chamber section 40 and discharge this surplus mist gas Msg to the outside via the pipes 33 and 33′. Furthermore, as disclosed in WO 2016/133131 A1, for example, the chamber section 40 is fixed between the slit-shaped nozzle opening 30A (not shown in FIG. 23) from which the mist gas Msg of the mist ejecting section 30 is ejected and the surface of the sheet substrate P, such that two electrode rods Ema and Emb, for irradiating the mist gas Msg sprayed from the mist ejecting section 30 onto the sheet substrate P with plasma that is not in thermal equilibrium, extend in the Y direction and are separated from each other by a certain interval in the X direction.

In the present modification, based on the findings of the preliminary experiment of FIG. 21, the temperature of the sheet substrate P passing below the chamber section 40 is reduced to be less than or equal to 0° C., e.g. −5° C., and the temperature of the mist gas Msg sprayed from the mist ejecting section 30 is set to a temperature at which the mist (pure water) does not freeze, e.g. approximately +5° C. to +10° C. Therefore, the adhered mist freezes and is deposited in a clouded frost-like state on the surface of the sheet substrate P passing below the chamber section 40. An observing section OVS for observing the surface state of the sheet substrate P is provided on the downstream side of the chamber section 40 in the sheet substrate P feeding direction (+X direction).

The observing section OVS is provided with two imaging units CV1 and CV2 arranged at prescribed intervals in the Y direction and at a certain height position upward (+Z direction) from the surface of the sheet substrate P and with an illuminating unit ILU that illuminates the imaged region on the sheet substrate P. The imaging range of the imaging unit CV1 is set in a manner to cover the region Aim spanning the −Y-direction half of the Y-direction width of the sheet substrate P, and the imaging unit CV2 is set in a manner to cover the region spanning the +Y-direction half of the Y-direction width of the sheet substrate P. The image information sequentially captured by the imaging units CV1 and CV2 is sent to an image analyzing unit (not shown in the drawings), and the image analyzing unit analyzes the state of the clouded frost (concentration distribution of cloudiness or the like) deposited on the surface of the sheet substrate P, to particularly identify regions where the clouding is thin.

A supplementary mist spraying section SMD is provided on the downstream side of the observing section OVS in the sheet substrate P feeding direction. The supplementary mist spraying section SMD includes a guide member 300 with a length in the Y direction greater than the width of the sheet substrate P and deposited above the sheet substrate P; a slider section 302 that is movable in the Y direction and is guided along a linear guide surface 300a formed on an X-direction side portion of the guide member 300; and a supplementary mist ejecting section 304 and supplementary mist recovering section 305A and 305B that are fixed to the slider section 302 and spray the mist gas Msg toward the surface of the sheet substrate P. Furthermore, a slot-shaped opening 300b extending in the Y-direction is formed in the X-direction center of the guide member 300, and the dimensions of the opening 300b are set such that a pipe mp1, which supplies the Msg to the supplementary mist ejecting section 304 while the slider section 302 moves in the Y direction, and a pipe mp2, which discharges the mist gas Msg′ collected by the supplementary mist recovering sections 305A and 305B, can pass therethrough.

A long and thin nozzle opening that ejects the mist gas Msg is formed in a floor surface portion of the supplementary mist ejecting section 304 facing the sheet substrate P, with an X-direction length shorter than the X-direction dimension of the region Aim and a Y-direction width that is less than or equal to several millimeters. Slit-shaped openings that suck in the mist gas Msg′ are formed respectively in the floor surface portions of the supplementary mist recovering sections 305A and 305B lined up in the Y direction in a manner to sandwich the supplementary mist ejecting section 304, and are arranged parallel to a slit-shaped nozzle opening formed in the floor surface portion of the supplementary mist ejecting section 304. The slider section 302 is driven by a drive source such as a linear motor such that the nozzle opening in the floor surface portion of the supplementary mist ejecting section 304 moves to a given Y-direction position within a range of the Y-direction width of the sheet substrate P.

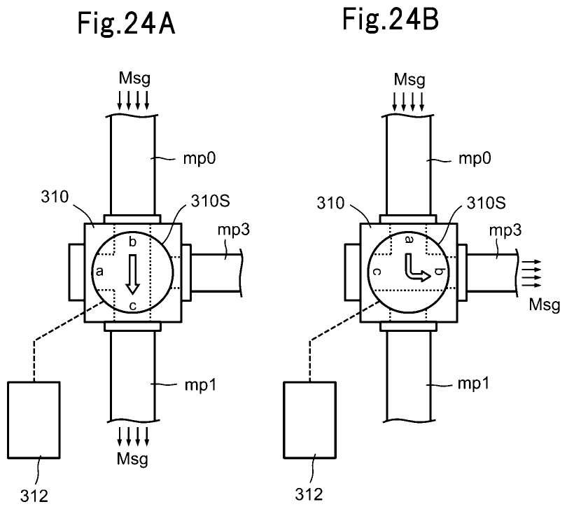

The supplementary mist ejecting section 304 performs additional localized mist deposition on portions where the deposited film thickness is low among the film deposited in a clouded frost-like state on the sheet substrate P observed by the imaging units CV1 and CV2 of the observing section OVS. Therefore, a mechanism is provided to spray the mist gas Msg toward the sheet substrate P from the nozzle opening in a short time, after the nozzle opening of the supplementary mist ejecting section 304 has been positionally set to face the region where the additional mist deposition is to be performed on the sheet substrate P. This mechanism is formed as shown in FIGS. 24A and 24B, for example. FIGS. 24A and 24B show a schematic configuration of a valve mechanism 310 provided in a flow path through which the mist gas Msg is supplied to the supplementary mist ejecting section 304. The valve mechanism 310 is connected to a pipe mp0 through which the mist gas Msg from the mist generating section 14 shown in FIG. 1 above is supplied, a pipe mp1 through which the mist gas Msg is sent out toward the supplementary mist ejecting section 304, and a pipe mp3 through which the mist gas Msg is sent out toward the mist gas collecting section 34 shown in FIG. 1 above.

The valve mechanism 310 includes a rotating valve portion 310S in which a T-shaped path is formed by three ports a, b, and c, in order to switch the flow path of the mist gas Msg by rotating back-and-forth by 90 degrees in the clockwise and counter-clockwise directions according to a plunger (drive source) 312. FIG. 24A shows a state (mist gas Msg supply state) in which the rotating valve portion 310S is positioned such that the mist gas Msg supplied from the pipe mp0 flows toward the pipe mp1 via the path from the port b through the port c. FIG. 24B shows a state (mist gas Msg non-supply state) in which the rotating valve portion 310S is switched to a state rotated 90 degrees clockwise from the state shown in FIG. 24A, such that the mist gas Msg supplied from the pipe mp0 flows toward the pipe mp3 via a path from the port a through the port b. Since the switching of the flow path by the rotating valve portion 310S is performed at high speed by the plunger (drive source) 312, it is possible to limit the spraying of the mist gas Msg from the supplementary mist ejecting section 304 toward the sheet substrate P to only a short time at a given timing.

In the modification described above, based on the deposition state (concentration distribution of clouded mist that has frozen in a frost-like state) on the sheet substrate P observed by the imaging units CV1 and CV2 of the observing section OVS, a portion where the deposition thickness is low on the sheet substrate P is identified, the slider section 302 moves such that the supplementary mist spraying section SMD (supplementary mist ejecting section 304) faces this portion, the rotating valve portion 310S of the valve mechanism 310 is temporarily switched from the state shown in FIG. 24B to the state shown in FIG. 24A, and additional mist deposition is performed only at the portion where the deposition thickness is low. Due to this, uneven thickness on the surface of the sheet substrate P that has passed under the supplementary mist depositing section SMD is reduced, and the thin film is formed by nanoparticles with improved evenness. The sheet substrate P that has passed by the supplementary mist depositing section SMD returns to the room temperature of approximately 25° C., for example, and the liquid film frozen to a frost-like state on the sheet substrate P undergoes a phase change to a liquid state and is dried. It should be noted that it is possible to provide a mechanism that applies an AC electric field to the liquid film on the surface of the sheet substrate P, such as shown in FIGS. 7, 13, and 14 above, on the downstream side of the mist deposition apparatus MDE shown in FIG. 23.

### Seventh Embodiment

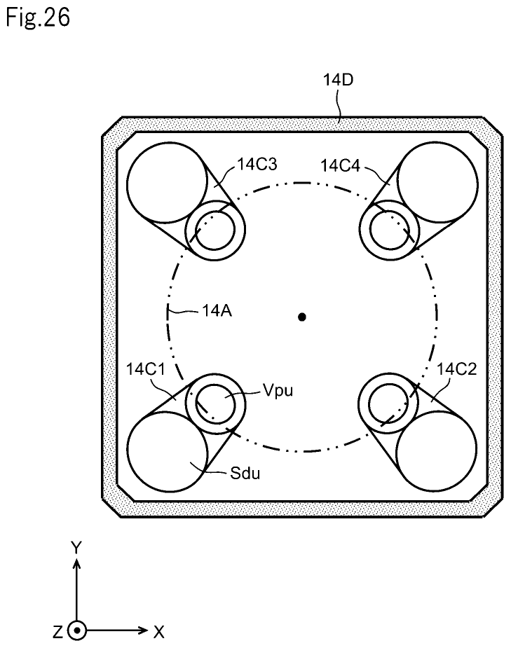

FIG. 25 is a partial cross-section view showing a modification of the mist generating section 14 shown in FIG. 1 wherein, for the convenience of the description, the Z axis of the orthogonal coordinate system XYZ is the direction of gravity (up-down direction), the XY plane is the horizontal plane, and a state is shown in which mist generating section 14 is cleaved along a plane parallel to the XZ plane. Furthermore, among the components in FIG. 25, components that have the same function as components of the mist generating section 14 in FIG. 1 are given the same reference numerals. FIG. 26 is a view of the floor surface side of the mist generating section 14 of FIG. 25 obtained by cleaving the mist generating section 14 at a Z-direction height of Cj with a plane parallel to the XY plane, as seen from above. Furthermore, the mist generating section 14 shown in FIGS. 25 and 26 can be used as the apparatus for generating the mist Msg used in each of the embodiments, modifications, and preliminary experiments above.

In FIG. 25, the mist generating section 14 includes an outer container 14D that has a square cross-sectional shape in the XY plane, has a plurality of ultrasonic oscillators 14C1, 14C2, etc. arranged on the floor portion, and is filled with a liquid (water) Wq for transmitting the ultrasonic vibration; an inner container (cup) 14A that has a circular cross-sectional shape in the XY plane, is installed in a manner to be immersed in the liquid Wq, and stores a prescribed volume of the liquid Lq serving as the source of the mist; a lid member 14E that supports the inner container 14A at a prescribed position in the space inside the outer container 14D and tightly closes the opening above the outer container 14D; and a lid member 14B that tightly closes the opening above the inner container 14A. The pipe 16 serving as an inflow port for allowing the carrier gas CGS to flow therein via the flow rate adjusting valve 15 shown in FIG. 1, the pipe 17 serving as an outflow port for ejecting the mist gas Msg, and the pipe 18 for replenishing the solution Lq are attached to the lid member 14B.

The height (Z-direction position) of the liquid surface of the solution Lq in the inner container 14A is set to be approximately half the height of the inner container 14A such that a suitable space is formed above the liquid surface, and to be approximately the same as the height of the liquid surface of the liquid Wq filling the outer container 14D. The inner container 14A is formed of a translucent polypropylene resin, and the outer container 14D is formed of a transparent acrylic resin. A tip portion (inflow port) 16E of the pipe 16 that guides the carrier gas CGS is bent at 90 degrees in a direction parallel to the liquid surface, such that the carrier gas CGS is not directly spouted onto the liquid surface of the solution Lq. Due to this, the carrier gas CGS ejected from the tip portion 16E is not spouted directly onto the liquid surface of the solution Lq and circulates along the cylindrical inner wall surface of the inner container 14A in the space above the liquid surface of the inner container 14A, and therefore restriction of the generation of mist floating up from the liquid surface of the solution Lq is avoided.

The ultrasonic oscillators 14C1, 14C2, etc. schematically shown in FIG. 25 are formed by ultrasonic oscillators 14C1, 14C2, 14C3, and 14C4 fixed respectively in the four corners on the floor portion of the outer container 14D, as shown in detail in FIG. 26. Each of the ultrasonic oscillators 14C1, 14C2, 14C3, and 14C4 is formed by a thin vibrating plate Vpu and a driving section Sdu housing a drive circuit, stored in a metal case with a waterproof structure. As shown in FIG. 26, each vibrating plate Vpu is arranged at a position near the periphery of the circular floor surface portion of the inner container 14A, when viewed in the XY plane. The four ultrasonic oscillators 14C1 to 14C4 are selectively driven (On/Off controlled) by a control circuit 400 supplying a drive signal and a power supply to the drive sections Sdu shown in FIG. 26. When all of the four ultrasonic oscillators 14C1 to 14C4 are being driven, it is possible to maximize the mist generation amount from the liquid surface of the solution Lq, and by reducing the number of the ultrasonic oscillators 14C1 to 14C4 being driven, it is possible to adjust (reduce) the mist generation amount. The control circuit 400 also controls the flow rate adjusting valve 15 that adjusts the flow rate of the carrier gas CGS.

When the throw-in type of ultrasonic oscillators 14C1 to 14C4 are driven for a long time (tens of minutes), the temperature thereof increases to tens of degrees Celsius, which causes the temperature of the surrounding liquid Wq to increase to approximately 40° C. The temperature of the liquid Wq is transmitted to the solution Lq as well via the inner container 14A, such that the temperature of the solution Lq also increases to approximately 40° C. Due to this, the temperature in the space above the liquid surface in the inner container 14A also increases, thereby increasing the temperature of the carrier gas CGS and the mist gas Msg to become greater than or equal to room temperature (25° C., for example). Therefore, the temperature increase of the mist gas Msg sprayed onto the sheet substrate P from the mist ejecting section 30 shown in each embodiment or modification causes a decrease in the adhesion efficiency of the mist onto the surface of the sheet substrate P. Accordingly, in the present modification, a cooler (temperature adjuster) 402 for lowering the temperature of the liquid Wq in the outer container 14D is provided. The cooler 402 supplies temperature-controlled liquid Wq into the outer container 14D with a prescribed flow rate via a supply pipe 14G and recovers and circulates the liquid Wq inside the outer container 14D from a recovery pipe 14H, based on a measured temperature from a temperature sensor 14S arranged inside the outer container 14D and temperature setting information from the control circuit 400.

The setting temperature of the liquid Wq is set to be less than or equal to room temperature, such as approximately 10° C., for example, and the cooler 402 performs feedback control of the temperature of the circulated liquid Wq such that the temperature measured by the temperature sensor 14S becomes the setting temperature (10° C.). Due to this, the mist gas Msg supplied to the mist ejecting section 30 (or to the supplementary mist spraying section SMD in FIG. 23) from the inner container 14A through the pipe 17 is set to a first temperature that is higher than 0° C. and less than or equal to 30° C., such as a temperature of approximately 10° C., for example. In a case where the liquid Wq is antifreeze (coolant such as ethylene glycol), the cooler 402 has a capability to reduce the temperature of the liquid Wq to be less than or equal to 0° C., such as a temperature near −20° C., for example. Furthermore, in a case where the solvent of the solution Lq stored in the inner container 14A is pure water, the temperature of the liquid Wq cannot be made less than or equal to 0° C. in order to avoid freezing, but if a surfactant is added to the pure water in order to control the aggregation of the nanoparticles serving as the solvent of the solution Lq, it is possible to make the freezing point temperature of the solution Lq be less than or equal to 0° C. Yet further, the carrier gas CGS guided into the space inside the inner container 14A from the pipe 16 serving as the inflow port shown in FIG. 25 may be set to approximately the same temperature as the solution Lq.

In the manner described above, in the mist generating section 14 that uses the throw-in type of ultrasonic oscillators 14C1 to 14C4, with the configuration whereby the ultrasonic vibration is transmitted to the solution Lq inside the inner container 14A via the liquid Wq, a temperature increase of the liquid Wq and a temperature increase of the solution Lq occur due to the heating of the ultrasonic oscillators 14C1 to 14C4, which results in the temperature of the mist generated from the liquid surface of the solution Lq increasing to be greater than or equal to room temperature. Due to this, the temperature of the mist gas Msg sprayed onto the sheet substrate P during the mist deposition becomes higher than the temperature of the surrounding environment (room temperature), which lowers the adhesion efficiency of the mist to the sheet substrate P, but by performing cooling with the cooler (temperature adjuster or temperature adjusting section) 402 to suppress the temperature increase of the liquid Wq such as in the present modification, the decrease in adhesion efficiency can be suppressed. Furthermore, by combining the present modification with the configuration for cooling the sheet substrate P such as shown in FIGS. 19 to 22 above, a relationship of (environmental temperature (room temperature))>(mist gas Msg temperature)>(sheet substrate P temperature) can be set, and the adhesion efficiency of the sprayed mist to the sheet substrate P can be improved.

According to the present modification, the mist generation apparatus that generates mist from the solution Lq in which fine particles are dispersed, in order to deposit the thin film made of nanoparticles of a material substance through mist deposition on the surface of the processing target that is the sheet substrate P, is configured as the mist generating section 14 that includes the inner container 14A storing the solution Lq such that a prescribed space is formed above the liquid surface; the outer container 14D that has the plurality of ultrasonic oscillators 14C1 to 14C4 for misting arranged on the floor portion, is filled with the liquid Wq for transmitting the ultrasonic vibration, and houses the inner container 14A in a manner to be immersed in the liquid Wq; the pipe 16 and tip portion 16E serving as an inflow port into which the carrier gas CGS flows at a prescribed flow rate in the space in the inner container 14A; the pipe 17 serving as an outflow port causing the mist generated from the liquid surface of the solution Lq in the inner container 14A due to the driving of the ultrasonic oscillators 14C1 to 14C4 and carried by the carrier gas CGS to flow out to the outside of the inner container 14A as the mist gas Msg; and the cooler (temperature adjuster) 402 serving as the temperature adjusting apparatus for adjusting the temperature of the solution Lq stored in the inner container 14A to be less than or equal to the surrounding environmental temperature. Furthermore, in the present modification, the cooler (temperature adjuster) 402 is configured to adjust the temperature of the solution Lq via the inner container 14A by reducing the temperature of the liquid Wq filling the outer container 14D to be less than or equal to the environmental temperature.

### [Other Modifications]

In each of the embodiments and modifications described above, in a case where the nanomaterials of the material substance contained in the mist sprayed onto the sheet substrate P as the mist gas Msg have a characteristic of being polarized, it is possible to smooth the film thickness distribution of the nanoparticles on the sheet substrate P by applying the AC electric field to the liquid film on the sheet substrate P formed after the mist deposition. In a case where the nanoparticles of the material substance for deposition do not have a characteristic of being polarized but do have a characteristic of being affected by magnetism, it is possible to improve the adhesion efficiency of the mist in the mist gas Msg to the sheet substrate P by embedding a magnetizer (permanent magnet, electromagnet, or the like) in the substrate support surface of the rotating drum DR or the support table 5D or 5D′ supporting the sheet substrate P. Furthermore, by applying an AC magnetic field to the liquid film on the sheet substrate P formed after the mist deposition, it is possible to smooth the film thickness distribution of the nanoparticles on the sheet substrate P.

In each of the embodiments and modifications described above, the mist generating section (mist generating apparatus) 14 atomized the solution Lq by using the ultrasonic oscillators 14C (14C1 to 14C4), but the mist generating section 14 may instead be configured to introduce a prescribed amount of powdered dry ice at prescribed time intervals into the inner container 14A storing the solution Lq, to generate the mist from the liquid surface of the solution Lq. In such a case, the space above the inner container 14A is filled with cold carbon dioxide gas (CO₂) generated by the vaporization of dry ice. This carbon dioxide gas, together with the carrier gas CGS supplied from the pipe 16 (tip portion 16E), becomes the mist gas Msg and is supplied to the mist ejecting section 30 via the pipe 17. The temperature of the mist gas Msg ejected from the nozzle opening 30A of the mist ejecting section 30 is lower than the surrounding environmental temperature (+20° C. to +30° C., for example), and therefore it is possible to improve the adhesion efficiency of the mist to the sheet substrate P.

In each of the embodiments and modifications described above, a configuration in which the deposited film of nanoparticles is formed by mist deposition on almost the entire surface of the sheet substrate P was provided as an example, but as disclosed in WO 2013/176222 A1, a portion with high liquid repellency and a portion that is highly lyophilic can be formed with a pattern exposure apparatus using ultraviolet rays on a layer of a photosensitive silane coupling agent after coating the surface of the sheet substrate P with this photosensitive silane coupling agent, and patterning can be performed to form the deposited film of nanoparticles on only a partial region on the sheet substrate P by actively adhering the mist to the portion that is highly lyophilic.

Alternatively, as in screen printing, mist deposition can be performed from above a mask plate made of a thin magnetic metal foil (preferably a stainless steel foil or the like with a thickness of 100 μm or less) having an opening formed in a portion thereof, in a state where the mask plate is firmly adhered to the surface of the sheet substrate P, to form the deposited film of nanoparticles only on the portion of the sheet substrate P corresponding to the opening in the mask plate. At this time, a configuration may be used in which a permanent magnet or electromagnet is embedded in the rotating drum DR or the support table 5D or 5D′ supporting the back surface of the sheet substrate P such that the mask plate is forcefully adhered to the surface of the sheet substrate P by a magnetic force. In such a case, the mask plate is peeled off from the surface of the sheet substrate P after the portion of the liquid film corresponding to the opening in the mask plate formed by the mist deposition on the sheet substrate P has dried. In the same manner as in each of the embodiments above, the sheet substrate P (or mask plate) can be cooled during the mist deposition, and an AC electric field can be applied to the liquid film during the drying of the liquid film to minutely vibrate the nanoparticles.

### DESCRIPTION OF REFERENCE NUMERALS

5A, 5B: roller
5C: belt
5D, 5D′: support table
10: solution tank
14: mist generating section
14C, 14C1 to 14C4: ultrasonic oscillator
16, 17, 18: pipe
30: mist ejecting section
30A: nozzle opening
31: mist supplying section
32, 32′: mist collecting section
40: chamber section (air guide mechanism)
60: mist charging apparatus
70: electrostatic field generating apparatus (electrostatic field generating section)
90, 92: AC electric field generating section
100: control section (CPU)
202: temperature adjusting (cooling) unit
212: temperature control unit
402: cooler (temperature adjuster)
AXo: center line
CGS: carrier gas
DR: rotating drum
Ea, Eb: electrode
Ec, Ed: electrode plate
Ef1 to Ef4, Em: electrode plate
Ef′, Em′: electrode line
HF: cooling pipe (heat exchange pipe)
Lq: solution
Msg: supplied mist gas
Msg′: discharged mist gas
np: nanoparticles (fine particles)
OVS: observing section
P: sheet substrate
SMD: supplementary mist spraying section
Wq: liquid

1. A deposition apparatus that supplies mist containing fine particles to a substrate and forms a film including the fine particles on a surface of the substrate, the deposition apparatus comprising:
an air guide member configured to cover at least a portion of the surface of the substrate; and
a mist supplying section configured to supply mist to a space between the surface of the substrate and the air guide member,
wherein:
the mist supplying section includes a charge applying section, which applies a positive or negative charge to the mist, and a mist ejecting section, which ejects the mist charged by the mist applying section into the space;
the air guide member has a wall surface facing the surface of the substrate; and
the deposition apparatus comprises an electrostatic field generating section configured to cause a potential having a same sign as the mist charged by the charge applying section to be generated by the wall surface.

2. The deposition apparatus according to claim 1, further comprising:
a feeding section configured to feed the substrate,
wherein the electrostatic field generating section includes a first electrode that causes a potential having the same sign as the mist to be generated by the wall surface and a second electrode that causes a potential having an opposite sign of the mist to be generated by the feeding section.

3. The deposition apparatus according to claim 2, wherein the electrostatic field generating section applies a voltage for which an absolute value of an average potential over time is greater than 0, between the first electrode and the second electrode.

4. The deposition apparatus according to claim 2, wherein the electrostatic field generating section applies an AC voltage that changes over time with a prescribed amplitude centered on an average potential whose absolute value is greater than 0, between the first electrode and the second electrode.

5. The deposition apparatus according to claim 2, wherein the feeding section includes a rotating drum that has a conductive outer circumferential surface supporting the substrate in an arc shape, and the outer circumferential surface is the second electrode.

6. A deposition apparatus that supplies mist containing fine particles to a substrate and forms a film including the fine particles on a surface of the substrate, the deposition apparatus comprising:
a mist generating section configured to atomize a liquid containing the fine particles to generate the mist; and
a mist supplying section configured to supply the mist to the substrate,
wherein the mist supplying section includes a temperature adjusting section that sets a temperature of the mist to a first temperature and a substrate temperature adjusting section that sets a temperature of the substrate to a second temperature.

7. The deposition apparatus according to claim 6, wherein the substrate temperature adjusting section sets the second temperature to be lower than the first temperature.

8. The deposition apparatus according to claim 6, wherein:
the mist supplying section includes a support section that supports the substrate; and
the substrate temperature adjusting section adjusts a temperature of the support section to set the substrate to the second temperature.

9. The deposition apparatus according to claim 8, further comprising a feeding section configured to support and feed the substrate with the support section.

10. The deposition apparatus according to claim 9, wherein the feeding section supports and feeds the substrate in an arc shape and with the support section that includes a rotating drum.

11. The deposition apparatus according to claim 6, wherein the liquid is a dispersion in which the fine particles are dispersed in pure water or a liquid containing a surfactant.

12. The deposition apparatus according to claim 6, wherein the temperature adjusting section sets the first temperature in a manner that a temperature of a dispersion becomes a temperature in a range from 0° C. to 15° C.

13. The deposition apparatus according to claim 12, wherein the second temperature set by the substrate temperature adjusting section is set to a temperature that is lower than the first temperature and also in a range from 0° C. to 15° C.

14. A conductive film manufacturing apparatus comprising:
a deposition apparatus configured to supply mist containing fine particles to a substrate and form a film including the fine particles on a surface of the substrate; and
a drying section configured to dry the mist deposited on the substrate by the deposition apparatus,
wherein the deposition apparatus includes:
an air guide member configured to cover at least a portion of the surface of the substrate; and
a mist supplying section configured to supply mist to a space between the surface of the substrate and the air guide member, and
wherein the mist supplying section includes a charge applying section, which applies a positive or negative charge to the mist, and a mist ejecting section, which ejects the mist charged by the mist applying section into the space;
the air guide member has a wall surface facing the surface of the substrate; and
the deposition apparatus includes an electrostatic field generating section configured to cause a potential having a same sign as the mist charged by the charge applying section to be generated by the wall surface.

15. A deposition method for supplying mist containing fine particles to a substrate and forming a film including the fine particles on a surface of the substrate, the deposition method comprising:
supplying charged mist, by charging the mist to be positive or negative with a charge applying section, to a space between the surface of the substrate and an air guide member that covers at least a portion of the surface of the substrate, with a mist ejecting section; and
generating an electrostatic field by causing a potential having a same sign as the charged mist to be generated by a wall surface facing the surface of the substrate.

16. The deposition method according to claim 15, wherein:
the supplying of the charged mist includes supplying the mist to the substrate being fed by a feeding section; and
the generating of the electrostatic field includes causing a potential having the same sign as the mist to be generated by the air guide member with a first electrode and causing a potential having an opposite sign of the mist to be generated by the feeding section with a second electrode.

17. The deposition method according to claim 16, wherein the generating of the electrostatic field includes applying a voltage for which an absolute value of an average potential over time is greater than 0, between the first electrode and the second electrode.

18. The deposition method according to claim 16, wherein the generating of the electrostatic field includes applying an AC voltage that changes over time with a prescribed amplitude centered on an average potential whose absolute value is greater than 0, between the first electrode and the second electrode.

19. The deposition method according to claim 16, wherein the feeding section includes a rotating drum that has a conductive outer circumferential surface supporting the substrate in an arc shape, and the outer circumferential surface is the second electrode.

20. A deposition method for supplying mist containing fine particles to a substrate and forming a film including the fine particles on a surface of the substrate, the deposition method comprising:
generating the mist by atomizing a liquid containing the fine particles; and
supplying the mist to the substrate,
wherein the supplying of the mist includes setting a temperature of the mist to a first temperature with a temperature adjusting section and setting a temperature of the substrate to a second temperature with a substrate temperature adjusting section.

21. The deposition method according to claim 20, wherein the supplying of the mist includes setting the second temperature to be lower than the first temperature with the substrate temperature adjusting section.

22. The deposition method according to claim 20, wherein the supplying of the mist includes supporting the substrate with a support section and adjusting a temperature of the support section with the substrate temperature adjusting section to set the substrate to the second temperature.

23. The deposition method according to claim 22, wherein the supplying of the mist includes supporting and feeding the substrate with the support section, using a feeding section that includes the support section.

24. The deposition method according to claim 23, wherein the supplying of the mist includes supporting the substrate in an arc shape with the support section that includes a rotating drum.

25. The deposition method according to claim 20, wherein the liquid is a dispersion in which the fine particles are dispersed in pure water or a liquid containing a surfactant.

26. The deposition method according to claim 20, wherein the supplying of the mist includes setting the first temperature with the temperature adjusting section in a manner that a temperature of a dispersion becomes a temperature in a range from 0° C. to 15° C.

27. The deposition method according to claim 26, wherein in the supplying of the mist, the second temperature set by the substrate temperature adjusting section is set to a temperature that is lower than the first temperature and also in a range from 0° C. to 15° C.

28. A conductive film manufacturing method, comprising:
depositing a conductive film material on a substrate using a deposition method; and
drying the substrate on which a film has been deposited,
wherein the deposition method supplies mist containing fine particles to the substrate and forms the film including the fine particles on a surface of the substrate, and
the deposition method includes:
supplying charged mist, by charging the mist to be positive or negative with a charge applying section, to a space between the surface of the substrate and an air guide member that covers at least a portion of the surface of the substrate, with a mist ejecting section; and
generating an electrostatic field by causing a potential having a same sign as the charged mist to be generated by a wall surface facing the surface of the substrate.
